(19) United States
(12) Patent Application Publication
(10) Pub. No.: US 2026/0071029 A1
(43) Pub. Date: Mar. 12, 2026

(54) POLYIMIDE PRECURSOR COMPOSITION, POLYIMIDE FILM AND POLYIMIDE/SUBSTRATE LAMINATE

(71) Applicant: UBE Corporation, Ube-shi (JP)

(72) Inventors: Takuya OKA, Ube-shi (JP); Yuki NEMOTO, Ube-shi (JP); Yukinori KOHAMA, Ube-shi (JP); Taichi ITO, Ube-shi (JP)

(21) Appl. No.: 18/997,665

(22) PCT Filed: Jul. 27, 2023
(86) PCT No.: PCT/JP2023/027627

§ 371 Date: Nov. 24, 2025

(30) Foreign Application Priority Data
Jul. 29, 2022 (JP) 2022-122329
Sep. 2, 2022 (JP) 2022-140335
Feb. 28, 2023 (JP) 2023-029768

(51) Int. Cl. C08G 73/16; C03C 17/32; C08G 73/10; C08J 5/18; H01L 23/498

(52) U.S. Cl. CPC C08G 73/16; C03C 17/32; C08G 73/1042; C08J 5/18; C08J 2379/08; H10W 70/688

(57) ABSTRACT

Disclosed is a polyimide precursor composition comprising a polyimide precursor having a repeating unit represented by the following general formula (I) and at least one imidazole compound as an optional component in a predetermined amount. By using this composition, a polyimide film can be produced that has improved light transmittance and adhesion in a polyimide film/substrate laminate, while making use of the advantage of an aromatic polyimide film, such as heat resistance and coefficient of linear thermal expansion.

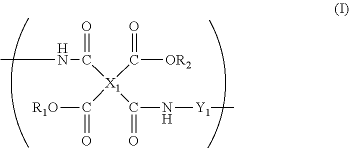

In the formula, X₁ contains (i) 50 mol % or more of a structure represented by formula (1-1) and contains 70 mol % or more of a structure represented by formula (1-1) and a structure represented by formula (1-2) in total; or contains (ii) 70 mol % or more of a structure represented by formula (1-1) and/or a structure represented by formula (1-2); and Y₁ contains the structure represented by formula (B) in an amount of 70 mol % or more. However, in the case of (ii) above, the polyimide precursor composition contains at least one imidazole compound in an amount of 0.01 mol or more and less than 1 mol per 1 mol of the repeating unit of the polyimide precursor.

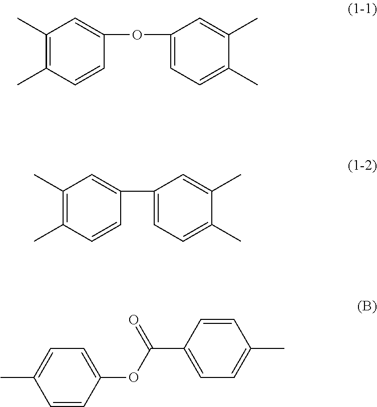

### TECHNICAL FIELD

The present invention relates to a polyimide precursor composition, a polyimide film and a polyimide/substrate laminate, which are suitably used for electronic device applications such as flexible device substrates.

### BACKGROUND ART

Polyimide films have been widely used in fields such as electric/electronic devices and semiconductors due to their excellent heat resistance, chemical resistance, mechanical strength, electrical properties, dimensional stability, and the like. With the coming of an advanced information society, the developments of optical materials such as an optical fiber and an optical waveguide in the field of optical communications, and a liquid crystal oriented film and a protective film for a color-filter in the field of display devices have recently advanced. In the field of display devices, in particular, the study of a plastic substrate which is light-weight and excellent in flexibility as an alternative to a glass substrate, and the development of a display which is capable of being bent and rolled have been intensively conducted. Accordingly, there is need for a higher-performance optical material which may be used for such purposes.

In displays such as liquid crystal displays and organic EL displays, semiconductor elements such as TFTs (thin film transistors) are formed for driving each pixel. Therefore, the substrate is required to have heat resistance and dimensional stability. Since polyimide films have excellent heat resistance, chemical resistance, mechanical strength, electrical properties, dimensional stability, and the like, they are promising material for substrates in display applications.

In general, since it is difficult to maintain the planarity of a flexible film, it is difficult to uniformly and precisely form semiconductor elements such as TFTs, fine wiring, and the like on a flexible film. In order to solve this problem, for example, Patent Document 1 describes “a method for manufacturing a flexible device that is a display device or a light-receiving device, including the steps of forming a solid polyimide resin film by applying a specific precursor resin composition onto a carrier substrate, forming a circuit on the resin film, and peeling off the solid resin film on which the circuit is formed from the carrier substrate”.

Patent Document 2 discloses a method of manufacturing a flexible device, which includes forming elements and circuits necessary for a device on a polyimide film/glass substrate laminate obtained by forming a polyimide film on a glass substrate, and thereafter irradiating laser from the glass substrate side to peel off the glass substrate.

In the manufacturing methods of flexible electronic devices described in Patent Documents 1 and 2, appropriate adhesion between the polyimide film and the glass substrate is necessary for handling the polyimide film/glass substrate laminate.

Polyimide is generally colored in yellowish brown, which limits its use in transmissive devices such as liquid crystal displays equipped with a backlight. In recent years, however, polyimide films with excellent light transmittance have been developed, and expectations are rising for use as substrates in display applications. For example, Patent Document 3 describes a semi-alicyclic polyimide that is excellent in optical transparency as well as mechanical properties and heat resistance.

On the other hand, as aromatic polyimides for flexible electronic device substrates, for example, Patent Documents 4 and 5 disclose polyimides using a diamine component containing a fluorine-containing aromatic diamine such as 2,2′-bis(trifluoromethyl)benzidine (TFMB). In addition, Patent Documents 6, 7, and 8 disclose examples of using a diamine component containing an aromatic diamine compound containing an ester bond for the same purpose. Polyimides containing an aromatic diamine compound containing an ester bond are also known for use in copper-clad laminates (for example, Patent Document 9) and for forming release layers (Patent Document 10). In addition, Patent Documents 11 to 15 also disclose examples of using a diamine component containing an aromatic diamine compound containing an ester bond.

### CITATION LIST

### Patent Document

Patent Document 1: Japanese Patent Laid-Open No. 2010-202729
Patent Document 2: WO 2018/221607
Patent Document 3: WO 2012/011590
Patent Document 4: WO 2009/107429
Patent Document 5: WO 2019/188265
Patent Document 6: Japanese Patent Laid-Open No. 2021-175790
Patent Document 7: WO 2017/051827
Patent Document 8: China Patent Application Publication No. 110003470
Patent Document 9: Japanese Patent Laid-Open No. 2021-195380
Patent Document 10: WO 2016/129546
Patent Document 11: WO 2021/261177
Patent Document 12: U.S. Patent Application Publication No. 2022/0135797
Patent Document 13: Japanese Patent Laid-Open No. H7-133349
Patent Document 14: Japanese Patent Laid-Open No. 2020-164704
Patent Document 15: U.S. Patent Application Publication No. 2021/0017336

### SUMMARY OF THE INVENTION

### Technical Problem

In recent years, the film formation method for TFTs has been improved, and the film formation temperature has been lowered compared to the past. However, high-temperature processing is still necessary in certain processes. In addition, since the larger process margin result in the better yield, it is preferable that the heat resistance of the substrate film is as high as possible. Although aromatic polyimides have a problem in terms of coloration, they generally have excellent heat resistance, and therefore if coloration can be reduced as much as possible, they may be used as substrates for displays.

In particular, in smartphones and the like equipped with under-display cameras, light reaches the camera through the display, and therefore polyimide films for such displays are required to have high light transmittance, particularly in the sensitivity range of the sensor. Also, required is a high elastic modulus, for example, to prevent whitening at the folded parts of bendable flexible displays.

As mentioned above, Patent Documents 4 and 5 disclose examples of the use of 2,2′-bis(trifluoromethyl)benzidine (TFMB), but the present inventors have conducted further research and discovered a problem that, in the process of forming an electronic device from a polyimide film/glass substrate laminate using TFMB as a monomer component, the polyimide film tends to peel off from the glass substrate. Peeling is likely to occur when an inorganic thin film having a gas barrier function is formed on the polyimide film/glass substrate laminate and the laminate is exposed to high temperatures.

In addition, the manufacture of flexible electronic devices may include a process of cutting a large polyimide film/glass substrate laminate (including after element formation) into individual flexible electronic devices (intermediate products). If the adhesion between the polyimide film and the glass substrate is insufficient, peeling may occur between the polyimide film and the glass substrate in this process. The reason is presumed that since polyimide has a tendency to absorb moisture, it absorbs moisture in the air from the edge face after cutting (the upper part is a barrier film) and expands, which leads to peeling if the adhesion is weak. In addition, in the laser lift-off process in which the polyimide film is peeled off from the glass substrate, if the adhesion strength between the polyimide film and the glass substrate is high, the laser intensity can be lowered, and therefore the polyimide changes little (or no change) after this processing. Whereas, if the adhesion is weak, the laser intensity needs to be increased, which may cause change of color or a decrease in mechanical properties of the polyimide after processing. Therefore, the adhesion between the polyimide film and the glass substrate, i.e., the peel strength, is required to be extremely high.

The above-mentioned Documents 6 to 15 do not disclose the present invention at all, and furthermore have problems as polyimide films for flexible display substrates. Patent documents 6 and 7 disclose examples of the use of diamine components including 4-aminophenyl-4-aminobenzoate (APAB; abbreviated as 4-BAAB in the present application), but are insufficient in terms of the color of the film. Patent document 8 requires a diamine compound with a specific structure, and is insufficient in terms of the color of the film and elastic modulus. The polyimide precursor compositions described in Patent documents 11, 14, and 15 also require a diamine compound with a specific structure, and are not satisfactory in terms of properties for flexible display substrate applications such as haze. Moreover, the polyimide films described in Patent documents 9, 10, 12, and 13, which are obtained from the polyimide precursor compositions for other use applications, do not satisfy properties required for display applications, including adhesion.

Therefore, an object of the present invention is to provide a polyimide precursor composition for producing a polyimide film for flexible electronic device applications, particularly for flexible display substrate applications, which has light transparency, adhesion in a polyimide film/substrate laminate, and the like, while making use of the advantages of an aromatic polyimide film, such as heat resistance and linear thermal expansion coefficient, and the like. A further object of the present invention is to provide a polyimide film and a polyimide film/substrate laminate obtained from this polyimide precursor.

### Solution to Problem

The main disclosures of the present application are summarized as follows. The inventions relating to items A1 to A14 are referred to as Invention Series A, and the inventions relating to items B1 to B12 are referred to as Invention Series B.

The inventions of the Invention A series are as follows.
A1. A polyimide precursor composition, comprising a polyimide precursor having a repeating unit represented by the following general formula (I) and at least one imidazole compound as an optional component in an amount of less than 1 mol per 1 mol of a repeating unit of the polyimide precursor:

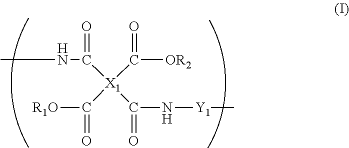

(wherein in general formula I, X₁ is a tetravalent aliphatic group or aromatic group, Y₁ is a divalent aliphatic group or aromatic group, R₁ and R₂ are each independently a hydrogen atom, an alkyl group having 1 to 6 carbon atoms or an alkylsilyl group having 3 to 9 carbon atoms, wherein,
X₁ satisfies either (i) or (ii);
(i) X₁ comprises a structure represented by formula (1-1) in an amount of 50 mol % or more, and comprises a structure represented by formula (1-1) and a structure represented by formula (1-2) in an amount of 70 mol % or more in total;
(ii) X₁ comprises a structure represented by formula (1-1) and/or a structure represented by formula (1-2) in an amount of 70 mol % or more;

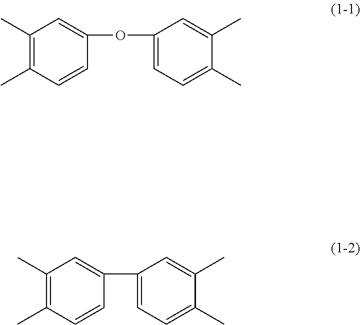

Y₁ comprises a structure represented by formula (B) in an amount of 70 mol % or more.

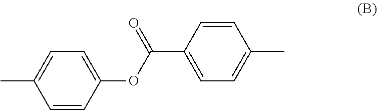

with the proviso that, in the case of (ii) above, the polyimide precursor composition comprises at least one imidazole compound as an essential component in an amount of 0.01 mol or more and less than 1 mol per 1 mol of the repeating unit of the polyimide precursor.
A2. The polyimide precursor composition according to the above item A1, wherein 60 mol % or more of X₁ is a structure represented by formula (1-1).
A3. The polyimide precursor composition according to any one of the above items, wherein 80 mol % or more of Y₁ has a structure represented by formula (B).
A4. The polyimide precursor composition according to any one of the above items, further comprising at least one imidazole compound in an amount of 0.01 mol or more and less than 1 mol per 1 mol of a repeating unit of the polyimide precursor.
A5. The polyimide precursor composition according to the above item A4, wherein the imidazole compound is at least one selected from the group consisting of 1,2-dimethylimidazole, 1-methylimidazole, 2-methylimidazole, 2-phenylimidazole, 1-phenylimidazole, imidazole and benzimidazole.
A6. The polyimide precursor composition according to any one of the above items, comprising at least one silane compound having a Si—OR^{a} structure (wherein R^{a} is a hydrogen atom or a hydrocarbon group) in an amount of more than 0 part by mass and 60 parts by mass or less based on 100 parts by mass of the total of the tetracarboxylic dianhydride and the diamine compound used in producing the polyimide precursor composition.
A7. The polyimide precursor composition according to the above item A6, wherein the silane compound is represented by formula:

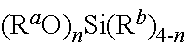

(wherein n is an integer of 1 to 4, R^{a} is a hydrogen atom or a straight chain or branched alkyl group having 1 to 8 carbon atoms, and R^{b} is an alkyl group or aryl group having 10 or less carbon atoms).
A8. A polyimide film obtained from the polyimide precursor composition according to any one of the above items.
A9. A polyimide film/substrate laminate comprising:
a polyimide film obtained from the polyimide precursor composition according to any one of the above items, and
a substrate.
A10. The laminate according to the above item A9, further comprising an inorganic thin film layer on the polyimide film of the laminate.
A11. The laminate according to any one of the above items, wherein the substrate is a glass substrate.
A12. A method for producing a polyimide film/substrate laminate, comprising:
(a) applying the polyimide precursor composition according to any one of the above items onto a substrate; and
(b) heat-treating the polyimide precursor on the substrate to laminate a polyimide film on the substrate.
A13. The method for producing a laminate according to the above item A12, further comprising, after step (b),
(c) forming an inorganic thin film layer on the polyimide film of the laminate.
A14. A method for manufacturing a flexible electronic device, comprising:
(d) forming at least one layer selected from a conductive layer and a semiconductor layer on the inorganic thin film layer of the laminate produced according to the above item A13; and
(e) peeling the polyimide film from the substrate.
A15. A flexible electronic device comprising the polyimide film according to the above item A8.
A16. A flexible electronic device substrate comprising the polyimide film according to the above item A8.

The present specification also discloses inventions of the Invention B series, which are inventions having different aspects from those described above.
B1. A polyimide precursor composition, comprising
a polyimide precursor having a repeating unit represented by the following general formula (I), and
at least one imidazole compound in an amount of 0.01 mol or more and less than 1 mol per 1 mol of a repeating unit of the polyimide precursor.

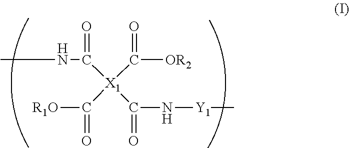

(wherein in general formula I, X₁ is a tetravalent aliphatic group or aromatic group, Y₁ is a divalent aliphatic group or aromatic group, R₁ and R₂ are each independently a hydrogen atom, an alkyl group having 1 to 6 carbon atoms or an alkylsilyl group having 3 to 9 carbon atoms, wherein,
X₁ comprises a structure represented by formula (1-1) and/or a structure represented by formula (1-2) in an amount of 70 mol % or more;

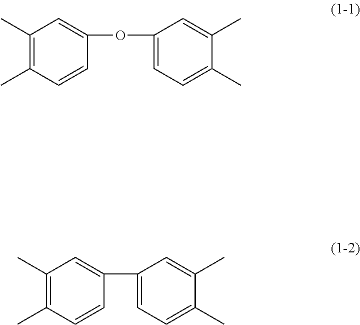

Y₁ comprises a structure represented by formula (B) in an amount of 50 mol % or more;

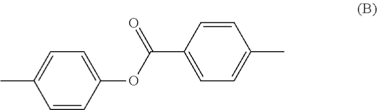

B2. The polyimide precursor composition according to the above item B1, wherein 40 mol % or more of X₁ is a structure represented by formula (1-1).
B3. The polyimide precursor composition according to any one of the above items, wherein 60 mol % or more of Y₁ has a structure represented by formula (B).

The polyimide precursor composition according to any one of the above items, wherein X₁ comprises a structure represented by formula (1-1) and a structure represented by formula (1-2) in an amount of 60 mol % or more in total.
B5. The polyimide precursor composition according to any one of the above items, wherein the imidazole compound is at least one selected from the group consisting of 1,2-dimethylimidazole, 1-methylimidazole, 2-methylimidazole, 2-phenylimidazole, 1-phenylimidazole, imidazole and benzimidazole.
B6. A polyimide film obtained from the polyimide precursor composition according to any one of the above items.
B7. A polyimide film/substrate laminate comprising:
a polyimide film obtained from the polyimide precursor composition according to any one of the above items, and
a substrate.
B8. The laminate according to the above item B7, further comprising an inorganic thin film layer on the polyimide film of the laminate.
B9. The laminate according to any one of the above items, wherein the substrate is a glass substrate.
B10. A method for producing a polyimide film/substrate laminate, comprising:
(a) applying the polyimide precursor composition according to any one of the above items onto a substrate; and
(b) heat-treating the polyimide precursor on the substrate to laminate a polyimide film on the substrate.
B11. The method for producing a laminate according to the above item B10, further comprising, after step (b),
(c) forming an inorganic thin film layer on the polyimide film of the laminate.
B12. A method for manufacturing a flexible electronic device, comprising:
(d) forming at least one layer selected from a conductive layer and a semiconductor layer on the inorganic thin film layer of the laminate produced according to the above B11; and
(e) peeling the polyimide film from the substrate.

### Advantageous Effects of Invention

According to the present invention, provided is a polyimide precursor composition for producing a polyimide film having improved light transmittance and adhesion in a polyimide film/substrate laminate while making use of the advantages of an aromatic polyimide film such as heat resistance and linear thermal expansion coefficient. That is, the polyimide precursor composition of the present invention is optimal for producing a polyimide film used as a flexible display substrate. Furthermore, the present invention can provide a polyimide film and a polyimide film/substrate laminate obtained from this polyimide precursor.

In addition, according to one embodiment of the present invention, a polyimide precursor composition having a more stable viscosity can be provided.

Further, according to one aspect of the present invention, it is possible to provide a polyimide film and a polyimide film/substrate laminate obtained using the polyimide precursor composition. Furthermore, according to another aspect of the present invention, it is possible to provide a method for manufacturing a flexible electronic device and a flexible electronic device using the polyimide precursor composition.

### DESCRIPTION OF EMBODIMENTS

In the present application, the term “flexible (electronic) device” means that the device itself is flexible, and the device is usually completed by forming semiconductor layers (transistors, diodes and the like as elements) on a substrate. A “flexible (electronic) device” is distinguished from conventional devices such as COF (Chip On Film) in which a “hard” semiconductor element such as an IC chip is mounted on a FPC (Flexible Printed Circuit Board). However, in order to operate or control the “flexible (electronic) device” of the present application, “hard” semiconductor elements such as IC chips may be used in combination by mounting them on the flexible substrate, or electrically connecting them. Suitable flexible (electronic) devices include display devices, for example, flexible displays such as liquid crystal displays and organic EL displays, and electronic papers, and light receiving devices such as solar cells and CMOS.

More specifically, the term “flexible (electronic) device substrate” does not include flexible wiring boards (also called flexible substrates, flexible printed wiring boards, and the like.).

In the present application, when the terms “for flexible (electronic) device substrate” and “for flexible display substrate” are used with respect to polyimide film, it means that the polyimide film itself is the main component of the substrate (or the substrate itself) present in the final product, and does not mean films and layers not present in the final product, or accessory layers laminated to the substrate. As a specific example, a release layer is not a substrate.

When the terms “for flexible (electronic) device substrate” and “for flexible display substrate” are used with respect to a polyimide precursor composition, they refer to a polyimide precursor composition for directly producing a polyimide film for the substrate, and specifically, the polyimide precursor composition is applied onto a substrate and imidized to obtain a polyimide film “for flexible (electronic) device substrate (including flexible display substrate; the same applies below)”. Therefore, for example, when two or more polyimide precursor compositions (intermediate compositions) are mixed and used to produce a polyimide film, each polyimide precursor composition is not “for flexible (electronic) device substrate” as defined in this application. This is because the structure of the resulting polyimide film depends on the structure of the polyimide precursor composition for directly producing the polyimide film.

Furthermore, although copper (or metal) clad laminates are used to produce flexible wiring boards (flexible substrates, flexible printed wiring boards), they are not used to produce flexible (electronic) devices, and therefore polyimide precursor compositions for producing copper clad laminates are not polyimide precursor compositions for “flexible (electronic) device substrates.” The definitions of the above terms may be explained in further detail in this specification.

The polyimide precursor composition of the present invention will be described below, followed by a description of a method for producing a flexible electronic device. The following description will focus on the Invention A series. The Invention B series, which comprises an imidazole compound as an essential component, will be described in the section on imidazole compounds. Unless there is a contradiction, the description of the Invention A series also applies to the invention of the Invention B series.

### <<Polyimide Precursor Composition>>

The polyimide precursor composition for forming a polyimide film comprises a polyimide precursor. In a preferred embodiment, the polyimide precursor composition further comprises a solvent, and the polyimide precursor is dissolved in the solvent.

The polyimide precursor includes a repeating unit represented by the following general formula (I):

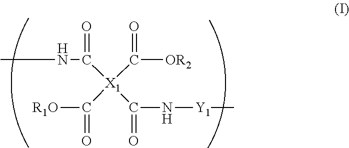

(wherein in general formula I, X₁ is a tetravalent aliphatic group or aromatic group, Y₁ is a divalent aliphatic group or aromatic group, R₁ and R₂ are each independently a hydrogen atom, an alkyl group having 1 to 6 carbon atoms or an alkylsilyl group having 3 to 9 carbon atoms.).

Particularly preferred are polyamic acids in which R₁ and R₂ are hydrogen atoms. When X₁ and Y₁ are aliphatic groups, the aliphatic group is preferably a group having an alicyclic structure.

In all repeating units of the polyimide precursor, X₁ comprises a structure represented by formula (1-1) in an amount of 50 mol % or more, and comprises a structure represented by formula (1-1) and a structure represented by formula (1-2) in an amount of 70 mol % or more in total. Herein formula (1-1) and formula (1-2) are structures derived from oxydiphthalic dianhydride (abbreviation: ODPA) and 3,3′,4,4′-biphenyltetracarboxylic dianhydride (abbreviation: s-BPDA), respectively.

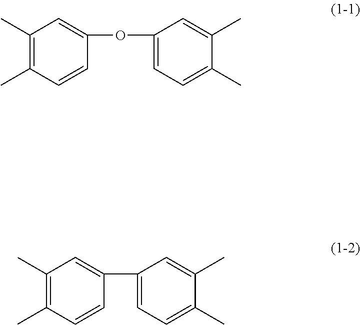

In addition, 70 mol % or more of Y₁ is a structure represented by formula (B), that is, a structure derived from 4-aminophenyl-4-aminobenzoate (abbreviation: 4-BAAB).

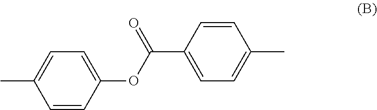

The use of a composition containing such a polyimide precursor enables to produce a polyimide film having high light transmittance and high elastic modulus as well as improved adhesion in a polyimide film/substrate laminate. The obtained polyimide film is also excellent in properties such as heat resistance and low linear thermal expansion coefficient, which are advantages of a wholly aromatic polyimide film.

The polyimide precursor will be explained in terms of monomers (tetracarboxylic acid component, diamine component, and other components) that provide X₁ and Y₁ in the general formula (I), and then the production method will be explained.

In the present specification, the tetracarboxylic acid component includes tetracarboxylic acid, tetracarboxylic dianhydride, and other tetracarboxylic acid derivatives such as tetracarboxylic acid silyl ester, tetracarboxylic acid ester and tetracarboxylic acid chloride, each of which is used as a starting material for producing a polyimide. Although not particularly limited, it is convenient to use tetracarboxylic acid dianhydride from the view point of production, and the following description will be made to examples using tetracarboxylic acid dianhydride as a tetracarboxylic acid component. Further, the diamine component is a diamine compound having two amino groups (—NH₂), which is used as a starting material for producing a polyimide.

In the present specification, the term “polyimide film” refers to both a film formed on a (carrier) substrate and present in a laminate, and a film that has been separated from the substrate after peeling. The material constituting the polyimide film, i.e., the material obtained by heat-treating (imidizing) a polyimide precursor composition, may be referred to as a “polyimide material.”

### <X₁ and Tetracarboxylic Acid Component>

As described above, (i) or (ii) is satisfied.
(i) In all repeating units of the polyimide precursor, preferably 50 mol % or more of X₁ is a structure represented by the following formula (1-1) (derived from ODPA), and preferably the total amount of the structure represented by formula (1-1) (derived from ODPA) and the structure represented by formula (1-2) (derived from s-BPDA) is 70 mol % or more of X₁.
(ii) If condition that an imidazole compound described later is contained in an amount of 0.01 mol or more and less than 1 mol per 1 mol of the repeating unit of the polyimide precursor is satisfied, the total amount of the structure represented by formula (1-1) (derived from ODPA) and the structure represented by formula (1-2) (derived from s-BPDA) is preferably 70 mol % or more of X₁, in which only one of the structure of formula (1-1) and the structure of formula (1-2) may be contained. In either case of (i) or (ii), X₁ may consist only of the structure of formula (1-1) and the structure of formula (1-2) (that is, the total amount of the structure of formula (1-1) and the structure of formula (1-2) is 100 mol %).

More preferably, 60 mol % or more of X₁ has the structure of formula (1-1), which is advantageous when high light transmittance is required. Even more preferably 70 mol % or more, even more preferably 80 mol % or more, and even more preferably 90 mol % or more of X₁ may have the structure of formula (1-1), and 100 mol % of X₁ may have the structure of formula (1-1).

In X₁, the total ratio of the structures of formula (1-1) and formula (1-2) is more preferably 75 mol % or more, further more preferably 80 mol % or more, and further more preferably 90 mol % or more, and 100 mol % is also preferable. Therefore, the ratio of the structure of formula (1-2) is 50 mol % or less, and may be 0%. If the structure of formula (1-2) is contained, the linear thermal expansion coefficient and mechanical properties (elastic modulus, and the like) can be improved, and if it is contained by, for example, 10 mol % to 40 mol %, these properties and light transmittance are improved in a well-balanced manner.

In the present invention, X₁ may comprise a tetravalent aliphatic or aromatic group other than the structures represented by formula (1-1) and formula (1-2) (hereinafter referred to as “other X₁”) in an amount that does not impair the effects of the present invention. As the aliphatic group, a tetravalent group having an alicyclic structure is preferable. Therefore, the tetracarboxylic acid component may contain “other tetracarboxylic acid derivatives” other than ODPA and s-BPDA in an amount of 30 mol % or less, more preferably 20 mol % or less, and even more preferably 10 mol % or less, based on 100 mol % of the tetracarboxylic acid component. It is also a preferred embodiment that the amount of “other tetracarboxylic acid derivatives” is 0 mol %.

When the proportion of the structure of formula (1-1) (derived from ODPA) in X₁ is less than 70 mol %, particularly less than 60 mol %, it is also preferable to include “other X₁” at a proportion of more than 0 mol %, for example, 10 mol % or more and 30 mol % or less, for example, 20 mol % or less. In this case, particularly preferred “other X₁” is tetravalent groups derived from tetracarboxylic dianhydrides having an aromatic ring containing a fluorine atom, such as 2,2-bis(3,4-dicarboxyphenyl)hexafluoropropane dianhydride (6FDA), and tetravalent groups derived from 2,3,3′,4′-biphenyltetracarboxylic dianhydride (a-BPDA). The “other X₁”, which are not limited to this case, will be described below.

As the “other X₁”, a tetravalent group having an aromatic ring is preferable, and a tetravalent group having an aromatic ring having 6 to 40 carbon atoms is preferable.

Examples of the tetravalent group having an aromatic ring include the following groups. However, the groups corresponding to the formulas (1-1) and (1-2) are excluded.

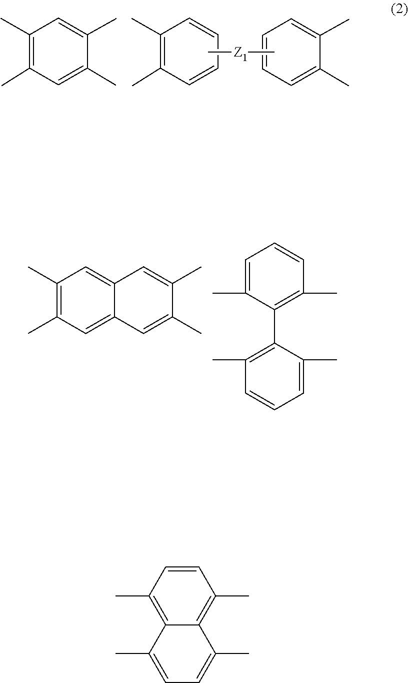

(wherein Z₁ is a direct bond, or any one of the following divalent groups:

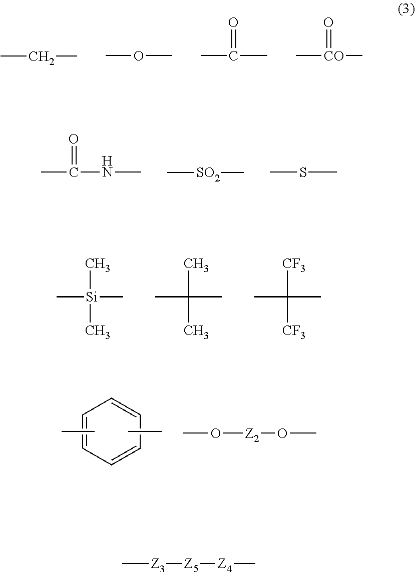

wherein Z₂ in the formula is a divalent organic group, Z₃ and Z₄ are each independently an amide bond, an ester bond or a carbonyl bond, and Z₅ is an organic group containing an aromatic ring.)

Specific examples of Z₂ include an aliphatic hydrocarbon group having 2 to 24 carbon atoms, and an aromatic hydrocarbon group having 6 to 24 carbon atoms.

Specific examples of Z₅ includes an aromatic hydrocarbon group having 6 to 24 carbon atoms.

Because the obtained polyimide film may have both high heat resistance and high light transmittance, the following group is particularly preferred as the tetravalent group having an aromatic ring.

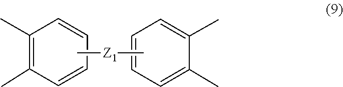

(wherein Z₁ is a direct bond, or a hexafluoroisopropylidene bond.)

Z₁ is more preferably a direct bond because the obtained polyimide film may have high heat resistance, high light transmittance, and low coefficient of linear thermal expansion.

In addition, preferred groups include a group in which Z₁ in the above formula (9) is a fluorenyl-containing group represented by the following formula (3A):

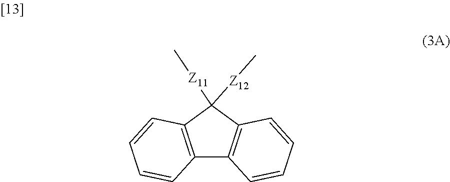

Z₁₁ and Z₁₂ are each independently, preferably the same, a single bond or a divalent organic group. Z₁₁ and Z₁₂ are preferably an organic group containing an aromatic ring, such as the formula (3A1):

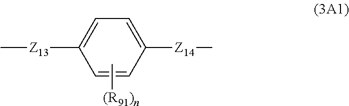

(Z₁₃ and Z₁₄ are each independently a single bond, —COO—, —OCO— or —O—, wherein when Z₁₄ is attached to a fluorenyl group, preferred is a structure in which Z₁₃ is —COO—, —OCO— or —O— and Z₁₄ is a single bond; R₉₁ is an alkyl group having 1 to 4 carbon atoms or a phenyl group, preferably methyl, and n is an integer of 0 to 4, and preferably 1.).

Examples of the tetracarboxylic acid component to provide a repeating unit of the formula (I) in which X₁ is a tetravalent group having an aromatic ring, include pyromellitic acid, 2,3,3′,4′-biphenyltetracarboxylic acid, 9,9-bis(3,4-dicarboxyphenyl)fluorene, 4-(2,5-dioxotetrahydrofuran-3-yl)-1,2,3,4-tetrahydronaphthalene-1,2-dicarboxylic acid, 3,3′,4,4′-benzophenonetetracarboxylic acid, 3,4′-oxydiphthalic acid, bis(3,4-dicarboxyphenyl)sulfone, m-terphenyl-3,4,3′,4′-tetracarboxylic acid, p-terphenyl-3,4,3′,4′-tetracarboxylic acid, biscarboxyphenyldimethylsilane, bisdicarboxyphenoxydiphenyl sulfide, sulfonyldiphthalic acid, and derivatives thereof, including tetracarboxylic dianhydride, tetracarboxylic acid silyl ester, tetracarboxylic acid ester, and tetracarboxylic acid chloride. Examples of the tetracarboxylic acid component to provide a repeating unit of the general formula (1) in which X₁ is a tetravalent group having a fluorine atom-containing aromatic ring include 2,2-bis(3,4-dicarboxyphenyl)hexafluoropropane, and derivatives thereof, including tetracarboxylic dianhydride, tetracarboxylic acid silyl ester, tetracarboxylic acid ester, and tetracarboxylic acid chloride. The tetracarboxylic acid component may be used alone or in combination of a plurality of types.

Examples of the tetracarboxylic acid component to provide a repeating unit of the formula (I) in which X₁ is a tetravalent group having an alicyclic structure include 1,2,3,4-cyclobutane tetracarboxylic acid, isopropylidenediphenoxybisphthalic acid, cyclohexane-1,2,4,5-tetracarboxylic acid, [1,1′-bi(cyclohexane)]-3,3′,4,4′-tetracarboxylic acid, [1,1′-bi(cyclohexane)]-2,3,3′,4′-tetracarboxylic acid, [1,1′-bi(cyclohexane)]-2,2′,3,3′-tetracarboxylic acid, 4,4′-methylenebis(cyclohexane-1,2-dicarboxylic acid), 4,4′-(propane-2,2-diyl)bis(cyclohexane-1,2-dicarboxylic acid), 4,4′-oxybis(cyclohexane-1,2-dicarboxylic acid), 4,4′-thiobis(cyclohexane-1,2-dicarboxylic acid), 4,4′-sulfonyl bis(cyclohexane-1,2-dicarboxylic acid), 4,4′-(dimethylsilanediyl)bis (cyclohexane-1,2-dicarboxylic acid), 4,4′-(tetrafluoropropane-2,2-diyl)bis (cyclohexane-1,2-dicarboxylic acid), octahydropentalene-1,3,4,6-tetracarboxylic acid, bicyclo[2.2.1]heptane-2,3,5,6-tetracarboxylic acid, 6-(carboxymethyl)bicyclo[2.2.1]heptane-2,3,5-tricarboxylic acid, bicyclo[2.2.2]octane-2,3,5,6-tetracarboxylic acid, bicyclo[2.2.2]octa-5-ene-2,3,7,8-tetracarboxylic acid, tricyclo[4.2.2.02,5]decane-3,4,7,8-tetracarboxylic acid, tricyclo[4.2.2.02,5]deca-7-ene-3,4,9,10-tetracarboxylic acid, 9-oxatricyclo[4.2.1.02,5]nonane-3,4,7,8-tetracarboxylic acid, norbornane-2-spiro-α-cyclopentanone-α′-spiro-2″-norbornane-5,5″,6,6″-tetracarboxylic acid, (4arH,8acH)-decahydro-1t,4t:5c,8c-dimethanonaphthalene-2c,3c,6c,7c-tetracarboxylic acid, (4arH,8acH)-decahydro-1t,4t:5c,8c-dimethanonaphthalene-2t,3t,6c,7c-tetracarboxylic acid, decahydro-1,4-ethano-5,8-methanonaphthalene-2,3,6,7-tetracarboxylic acid, and tetradecahydro-1,4:5,8:9,10-trimethanoanthracene-2,3,6,7-tetracarboxylic acid, and derivatives thereof, including tetracarboxylic dianhydride, tetracarboxylic acid silyl ester, tetracarboxylic acid ester, and tetracarboxylic acid chloride. The tetracarboxylic acid component may be used alone or in combination of a plurality of types.

### <Y₁ and Diamine Component>

As described above, among all repeating units in the polyimide precursor, preferably 70 mol % or more of Y₁ have the structure of formula (B), and is further more preferably 80 mol % or more, and 90 mol % or more in this order, and even 100 mol % is also preferable.

In the present invention, Y₁ may comprise a divalent aliphatic group or aromatic group other than the structure represented by formula (B) (hereinafter referred to as “other Y₁”) in an amount within a range that does not impair the effects of the present invention. That is, the diamine component may contain, in addition to 4-aminophenyl-4-aminobenzoate (4-BAAB), “other diamine compounds” in an amount of 30 mol % or less, more preferably 20 mol % or less, and even more preferably 10 mol % or less, based on 100 mol % of the diamine component. It is also a preferred embodiment that the amount of “other diamine compounds” is 0 mol %.

When the proportion of the structure of formula (1-1) (derived from 4-BAAB) is less than 90 mol %, particularly 80 mol % or less, it is also preferable to include “other Y₁” at a proportion of more than 0 mol %, for example 10 mol % or more and 20 mol % or less, for example 15 mol % or less. In this case, particularly preferred “other Y₁” is diamine compounds having an ether bond in the molecular chain direction, such as 4,4-oxydianiline (4,4-ODA) and 4,4′-bis(4-aminophenoxy)biphenyl (BAPB). The “other Y₁”, which is not limited to this case, will be described below.

In case that “other Y₁” is a divalent group having an aromatic ring, it is preferably a divalent group having an aromatic ring having 6 to 40 carbon atoms, more preferably 6 to 20 carbon atoms.

Examples of the divalent group having an aromatic ring include the following groups.

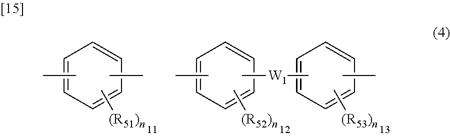

(wherein W₁ is a direct bond, or a divalent organic group; n₁₁ to n₁₃ each independently represent an integer of 0 to 4; and R₅₁, R₅₂ and R₅₃ are each independently an alkyl group having 1 to 6 carbon atoms, a halogen group, a hydroxyl group, a carboxyl group, or a trifluoromethyl group.)

Specific examples of W₁ include divalent groups represented by the formula (5) as described below, and divalent groups represented by the formula (6) as described below. However, the group corresponding to formula (B) is excluded.

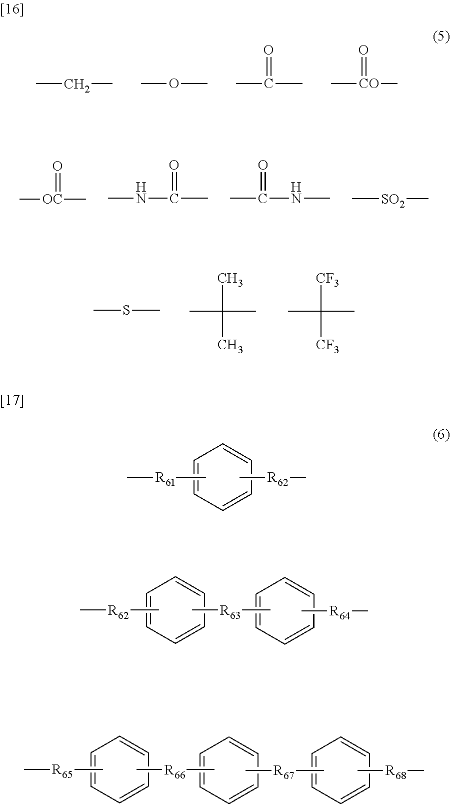

(wherein R₆₁ to R₆₈ in the formula (6) each independently represent any one of the divalent groups represented by the formula (5).)

Because the obtained polyimide may have high heat resistance, high light transmittance, and low coefficient of linear thermal expansion, W₁ herein is particularly preferably a direct bond, or one selected from the group consisting of groups represented by the formulas: —NHCO—, —CONH—, —COO— and —OCO—. In addition, W₁ is particularly preferably any one of the divalent groups represented by the formula (5) in which R₆₁ to R₆₈ are a direct bond, or one selected from the group consisting of groups represented by the formulas: —NHCO—, —CONH—, —COO— and —OCO—.

In addition, preferred groups include a group in which W₁ in the above formula (4) is a fluorenyl-containing group represented by the following formula (3B):

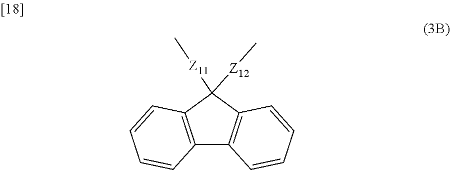

Z₁₁ and Z₁₂ are each independently, preferably the same, a single bond or a divalent organic group. Z₁₁ and Z₁₂ are preferably an organic group containing an aromatic ring, such as the formula (3B1):

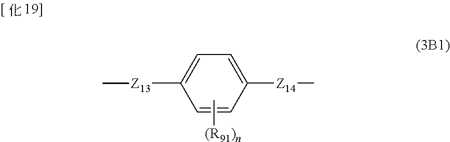

(Z₁₃ and Z₁₄ are each independently a single bond, —COO—, —OCO— or —O—, wherein when Z₁₄ is attached to a fluorenyl group, preferred is a structure in which Z₁₃ is —COO—, —OCO— or —O— and Z₁₄ is a single bond; R₉₁ is an alkyl group having 1 to 4 carbon atoms or a phenyl group, preferably methyl, and n is an integer of 0 to 4, and preferably 1.).

Another preferred group includes a compound in which W₁ in the above formula (4) is a phenylene group, that is, terphenyldiamine compounds, and particularly preferred are compounds in which all bondings are in para position.

Another preferred group includes a compound in which W₁ in the above formula (4) is a phenyl ring as depicted at first in formula (6) wherein R₆₁ and R₆₂ are 2,2-propylidene groups.

Still another preferred group includes a compound in which W₁ in the above formula (4) is represented by formula (3B2):

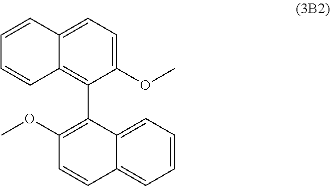 [SMILES: COc1ccc2ccccc2c1-c1c(OC)ccc2ccccc12]

Examples of the diamine component to provide Y₁, which is a divalent group having an aromatic ring, include p-phenylenediamine, m-phenylenediamine, benzidine, 3,3′-diamino-biphenyl, 3,3′-bis(trifluoromethyl) benzidine, m-tolidine, 3,4′-diaminobenzanilide, N,N′-bis(4-aminophenyl)terephthalamide, N,N′-p-phenylenebis(p-amino benzamide), 4-aminophenoxy-4-diaminobenzoate, bis(4-aminophenyl) terephthalate, biphenyl-4,4′-dicarboxylic acid bis(4-aminophenyl)ester, p-phenylenebis(p-aminobenzoate), bis(4-aminophenyl)-[1,1′-biphenyl]-4,4′-dicarboxylate, [1,1′-biphenyl]-4,4′-diyl bis(4-aminobenzoate), 4,4′-oxydianiline, 3,4′-oxydianiline, 3,3′-oxydianiline, p-methylenebis(phenylenediamine), 1,3-bis(4-aminophenoxy)benzene, 1,3-bis(3-aminophenoxy)benzene, 1,4-bis(4-aminophenoxy)benzene, 4,4′-bis(4-aminophenoxy)biphenyl, 4,4′-bis(3-amino phenoxy)biphenyl, 2,2-bis(4-(4-aminophenoxy)phenyl)hexafluoropropane, 2,2-bis(4-aminophenyl)hexafluoropropane, bis(4-aminophenyl)sulfone, 3,3′-bis(trifluoromethyl)benzidine, 3,3′-bis((aminophenoxy)phenyl)propane, 2,2′-bis(3-amino-4-hydroxyphenyl)hexafluoropropane, bis(4-(4-aminophenoxy) diphenyl)sulfone, bis(4-(3-aminophenoxy)diphenyl)sulfone, octafluorobenzidine, 3,3′-dimethoxy-4,4′-diaminobiphenyl, 3,3′-dichloro-4,4′-diaminobiphenyl, 3,3′-difluoro-4,4′-diaminobiphenyl, 2,4-bis(4-aminoanilino)-6-amino-1,3,5-triazine, 2,4-bis(4-aminoanilino)-6-methylamino-1,3,5-triazine, 2,4-bis(4-aminoanilino)-6-ethylamino-1,3,5-triazine, and 2,4-bis(4-amino anilino)-6-anilino-1,3,5-triazine. Examples of the diamine component to provide a repeating unit of the general formula (I) in which Y₁ is a divalent group having a fluorine atom-containing aromatic ring include 2,2′-bis(trifluoromethyl)benzidine, 3,3′-bis(trifluoromethyl)benzidine, 2,2-bis[4-(4-aminophenoxy)phenyl]hexafluoropropane, 2,2-bis(4-aminophenyl) hexafluoropropane, and 2,2′-bis(3-amino-4-hydroxyphenyl)hexafluoropropane. In addition, preferred diamine compounds include 9,9-bis(4-aminophenyl)fluorene, 4,4′-(((9H-fluorene-9,9-diyl)bis([1,1′-biphenyl]-5,2-diyl))bis(oxy))diamine, [1,1′ 0.4′,1″-terphenyl]-4,4″-diamine, 4,4′-([1,1′-binaphthalene]-2,2′-diylbis(oxy))diamine. The diamine component may be used alone or in combination of a plurality of types.

In case that “other Y₁” is a divalent group having an alicyclic structure, a divalent group having an alicyclic structure which has 4 to 40 carbon atoms is preferred, and it is more preferred that the group has at least one aliphatic 4- to 12-membered ring, more preferably an aliphatic 6-membered ring.

Examples of the divalent group having an alicyclic structure include the following groups.

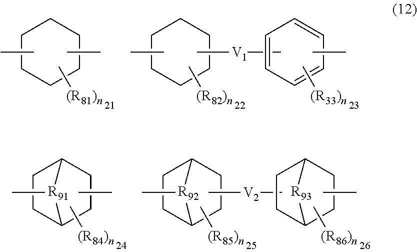

(wherein V₁ and V₂ are each independently a direct bond, or a divalent organic group; n₂₁ to n₂₆ each independently represent an integer of 0 to 4; R₈₁ to R₈₆ are each independently an alkyl group having 1 to 6 carbon atoms, a halogen group, a hydroxyl group, a carboxyl group, or a trifluoromethyl group; and R₉₁, R₉₂ and R₉₃ are each independently one selected from the group consisting of groups represented by the formulas: —CH₂—, —CH═CH—, —CH₂CH₂—, —O— and —S—)

Specific examples of V₁ and V₂ include a direct bond and divalent groups represented by the formula (5) as described above.

The diamine components giving Y₁ which is a divalent group having an alicyclic structure include, for example, 1,4-diaminocyclohexane, 1,4-diamino-2-methylcyclohexane, 1,4-diamino-2-ethylcyclohexane, 1,4-diamino-2-n-propylcyclohexane, 1,4-diamino-2-isopropylcyclohexane, 1,4-diamino-2-n-butylcyclohexane, 1,4-diamino-2-isobutylcyclohexane, 1,4-diamino-2-sec-butylcyclohexane, 1,4-diamino-2-tert-butylcyclohexane, 1,2-diaminocyclohexane, 1,3-diaminocyclobutane, 1,4-bis(aminomethyl)cyclohexane, 1,3-bis(aminomethyl)cyclohexane, diaminobicycloheptane, diaminomethylbicycloheptane, diaminooxybicycloheptane, diaminomethyloxybicycloheptane, isophoronediamine, diaminotricyclodecane, diaminomethyltricyclodecane, bis(aminocyclohexyl)methane, bis(aminocyclohexyl)isopropylidene, 6,6′-bis(3-aminophenoxy)-3,3,3′,3′-tetramethyl-1,1′-spirobiindane, and 6,6′-bis(4-aminophenoxy)-3,3,3′,3′-tetramethyl-1,1′-spirobiindane. The diamine component may be used alone or in combination of a plurality of types.

As tetracarboxylic acids component and diamine components giving the repeating unit represented by the general formula (I), although any of aliphatic tetracarboxylic acids (particularly dianhydrides) and/or aliphatic diamines other than alicyclic compounds may be used, the content thereof is preferably less than 30 mol %, more preferably less than 20 mol %, and even more preferably less than 10 mol % (including 0%) based on 100 mol % in total of the tetracarboxylic acid component and the diamine component.

By including the structure represented by formula (3B) as “other Y₁”, namely including a diamine compound such as 9,9-bis(4-aminophenyl)fluorene and the like as specific compounds, it may be possible to improve Tg and reduce the phase difference (retardation) in the film thickness direction.

In the present invention, notwithstanding the above description, in some cases it may be preferable that the polyimide precursor composition for producing a polyimide film does not contain a specific tetracarboxylic acid compound and/or a specific diamine compound, or a specific compound.
(a) It is preferred that the diamine compound represented by H₂N—Y₂—N═N—Y₂—NH₂ or H₂N—Y₂—NHNH—Y₂—NH₂(Y₂ is a divalent organic group) is contained in an extremely small amount (less than 5 moles in the repeating unit represented by general formula (I)) or is not contained at all.
(b) While a surfactant and an alkoxysilane compound may be added, it is also preferable that the composition does not contain a surfactant, and that the alkoxysilane compound does not include any compound other than the compounds that are described as preferable in the present invention.
(c) It is preferable that the composition does not contain any of a diamine compound having a —SO₂— group, a diamine compound having a fluorene structure, and a fluorine-containing diamine compound.
(d) It is preferable that the diamine component does not contain a diamine compound containing a benzamide structure, such as 3,5-diaminobenzamide, in an amount of 5 mol % or more, and it is further preferable that the diamine component does not contain it at all.
(e) It is preferable that the diamine compound represented by the following formula is not contained in an amount of 10:30 (=25:75) or more in a molar ratio relative to 4-BAAB, and even if it is contained, the molar ratio is more preferably 15:85 or less, further preferably 10:90 or less, and it is also preferable that it is not contained at all.

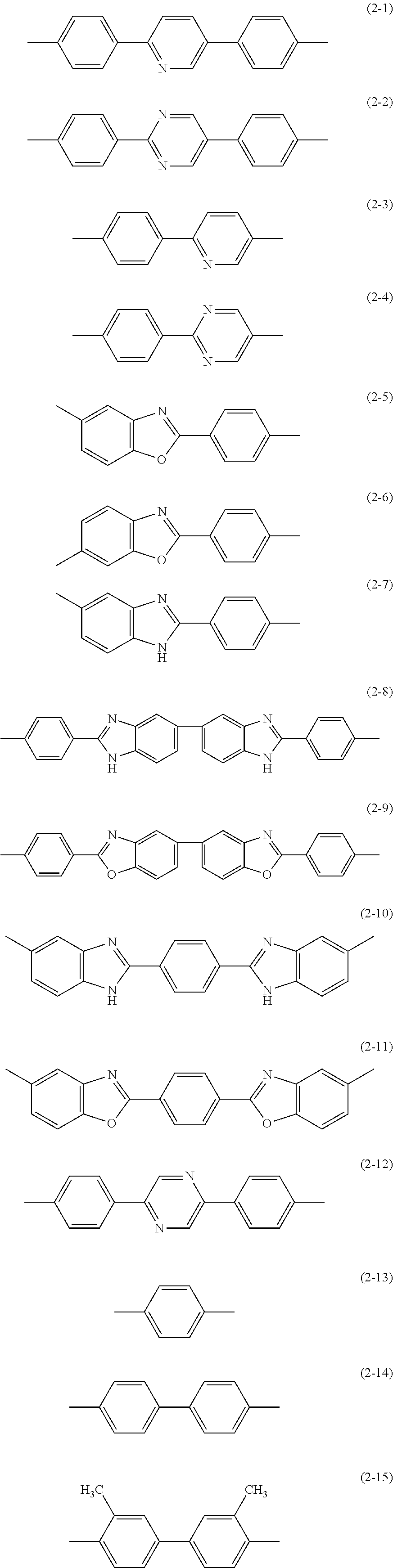

(f) It is preferable that the composition does not contain a combination of a tetracarboxylic dianhydride and a diamine compound which gives a repeating unit of the structure of the following formula:

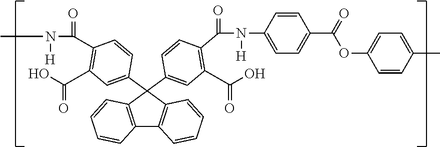

(g) It is preferable that the diamine component does not contain either 2,2′-bistrifluoromethylbenzidine or 1,4-diaminocyclohexane.
(h) It is preferred that the diamine component does not contain a diamine monomer containing a nitrogen heterocyclic structure in an amount of 3 to 8 mol %, and it is also preferred that it does not contain it at all.

A polyimide precursor can be produced from the above tetracarboxylic acid component and diamine component. According to the chemical structures of R₁ and R₂, the polyimide precursor used in the present invention (polyimide precursor comprising at least one repeating unit represented by the formula (I)) may be classified into:
1) polyamic acid (R₁ and R₂ are hydrogen),
2) polyamic acid ester (at least part of R₁ and R₂ is alkyl group), and
3) 4) polyamic acid silyl ester (at least part of R₁ and R₂ is alkylsilyl group).

Each class of the polyimide precursor may be easily produced by the production methods as described below. However, the method for producing the polyimide precursor used in the present invention is not limited to the production methods as described below.

### 1) Polyamic Acid

The polyimide precursor may be suitably obtained, in the form of a polyimide precursor solution, by reacting a tetracarboxylic dianhydride as a tetracarboxylic acid component and a diamine component in a substantially equimolar amount, preferably in a molar ratio of the diamine component to the tetracarboxylic acid component[molar number of the diamine component/molar number of the tetracarboxylic acid component] of 0.90 to 1.10, more preferably 0.95 to 1.05, in a solvent at a relatively low temperature of 120° C. or less, for example, while suppressing the imidization.

More specifically, the polyimide precursor may be obtained by dissolving the diamine in an organic solvent or water, adding the tetracarboxylic dianhydride to the resulting solution gradually while stirring the solution, and then stirring the solution at 0° C. to 120° C., preferably 5° C. to 80° C., for 1 hour to 72 hours, although the production method is not limited thereto. When they are reacted at 80° C. or more, the molecular weight may vary depending on the temperature history in the polymerization and the imidization may proceed by heat, and therefore the polyimide precursor may not be stably produced. The sequence of the addition of the diamine and the tetracarboxylic dianhydride in the production method as described above is preferred because the molecular weight of the polyimide precursor is apt to increase. Meanwhile, the sequence of the addition of the diamine and the tetracarboxylic dianhydride in the production method as described above may be reversed, and the sequence is preferred because the amount of the precipitate is reduced. When water is used as the solvent, an imidazole such as 1,2-dimethylimidazole, or a base such as triethylamine is preferably added thereto preferably in an amount of 0.8 equivalents or more relative to the carboxyl group of the formed polyamic acid (polyimide precursor).

### 2) Polyamic Acid Ester

A diester dicarboxylic acid chloride may be obtained by reacting a tetracarboxylic dianhydride and an arbitrary alcohol to provide a diester dicarboxylic acid, and then reacting the diester dicarboxylic acid and a chlorinating agent (thionyl chloride, oxalyl chloride, and the like). The polyimide precursor may be obtained by stirring the diester dicarboxylic acid chloride and a diamine at −20° C. to 120° C., preferably −5° C. to 80° C., for 1 hour to 72 hours. When they are reacted at 80° C. or more, the molecular weight may vary depending on the temperature history in the polymerization and the imidization may proceed by heat, and therefore the polyimide precursor may not be stably produced. The polyimide precursor may also be easily obtained by dehydrating/condensing a diester dicarboxylic acid and a diamine by the use of a phosphorus-based condensing agent, a carbodiimide condensing agent, or the like.

The polyimide precursor obtained by the method is stable, and therefore may be subjected to purification, including reprecipitation in which a solvent such as water and alcohols is added thereto.

### 3) Polyamic Acid Silyl Ester (Indirect Method)

A silylated diamine may be obtained by reacting a diamine and a silylating agent in advance. The silylated diamine may be purified by distillation, or the like, as necessary. And then, the polyimide precursor may be obtained by dissolving the silylated diamine in a dehydrated solvent, adding a tetracarboxylic dianhydride to the resulting solution gradually while stirring the solution, and then stirring the solution at 0° C. to 120° C., preferably 5° C. to 80° C., for 1 hour to 72 hours. When they are reacted at 80° C. or more, the molecular weight may vary depending on the temperature history in the polymerization and the imidization may proceed by heat, and therefore the polyimide precursor may not be stably produced.

### 4) Polyamic Acid Silyl Ester (Direct Method)

The polyimide precursor may be obtained by mixing a polyamic acid solution obtained by the method 1) and a silylating agent, and then stirring the resulting mixture at 0° C. to 120° C., preferably 5° C. to 80° C., for 1 hour to 72 hours. When they are reacted at 80° C. or more, the molecular weight may vary depending on the temperature history in the polymerization and the imidization may proceed by heat, and therefore the polyimide precursor may not be stably produced.

As for the silylating agent to be used in the method 3) and the method 4), the use of a silylating agent containing no chlorine is preferred because it is unnecessary to purify the silylated polyamic acid, or the obtained polyimide. Examples of the silylating agent containing no chlorine atom include N,O-bis(trimethylsilyl)trifluoroacetamide, N,O-bis(trimethylsilyl) acetamide, and hexamethyldisilazane. Among them, N,O-bis(trimethylsilyl) acetamide, and hexamethyldisilazane are particularly preferred, because they contain no fluorine atom and are inexpensive.

Meanwhile, in the silylation reaction of the diamine in the method 3), an amine catalyst such as pyridine, piperidine and triethylamine may be used so as to accelerate the reaction. The catalyst may be used, as it is, as a catalyst for the polymerization of the polyimide precursor.

As the solvent used in the production of the polyimide precursor, water, or aprotic solvents such as N,N-dimethylformamide, N,N-dimethylacetamide, N-methyl-2-pyrrolidone, N-ethyl-2-pyrrolidone, 1,3-dimethyl-2-imidazolidinone and dimethyl sulfoxide, for example, are preferred. However, any solvent may be used without any trouble on the condition that the starting monomer components and the formed polyimide precursor can be dissolved in the solvent, and therefore the solvent is not limited to the structures. As the solvent, water, or amide solvents such as N,N-dimethylformamide, N,N-dimethylacetamide, N-methyl-pyrrolidone and N-ethyl-2-pyrrolidone; cyclic ester solvents such as γ-butyrolactone, γ-valerolactone, δ-valerolactone, γ-caprolactone, ε-caprolactone and α-methyl-γ-butyrolactone; carbonate solvents such as ethylene carbonate and propylene carbonate; glycol solvents such as triethylene glycol; phenol solvents such as m-cresol, p-cresol, 3-chlorophenol and 4-chlorophenol; acetophenone, 1,3-dimethyl-2-imidazolidinone, sulfolane, dimethylsulfoxide, and the like may be preferably employed. In addition, other common organic solvents, namely, phenol, o-cresol, butyl acetate, ethyl acetate, isobutyl acetate, propyleneglycol methyl acetate, ethyl cellosolve, butyl cellosolve, 2-methyl cellosolve acetate, ethyl cellosolve acetate, butyl cellosolve acetate, tetrahydrofuran, dimethoxyethane, diethoxyethane, dibutyl ether, diethylene glycol dimethyl ether, methyl isobutyl ketone, diisobutyl ketone, cyclopentanone, cyclohexanone, methyl ethyl ketone, acetone, butanol, ethanol, xylene, toluene, chlorobenzene, turpentine, mineral spirits, petroleum naphtha-based solvents, and the like may be used. The solvent may be used in combination of a plurality of types.

The production of the polyimide precursor is not particularly limited, but the reaction is carried out by charging the monomers and the solvent at a concentration such that the solid content concentration (polyimide-converted mass concentration) of the polyimide precursor is, for example, 5 to 45% by mass.

The logarithmic viscosity of the polyimide precursor in a N-methyl-2-pyrrolidone solution at a concentration of 0.5 g/dL at 30° C. may be preferably 0.2 dL/g or more, more preferably 0.3 dL/g or more, particularly preferably 0.4 dL/g or more, although the logarithmic viscosity is not limited thereto. When the logarithmic viscosity is 0.2 dL/g or more, the molecular weight of the polyimide precursor is high, and therefore the obtained polyimide may have excellent mechanical strength and heat resistance.

### <Imidazole Compound>

The polyimide precursor composition may contain at least one kind of imidazole compound. The imidazole compound is not particularly limited as long as it has an imidazole skeleton, and examples thereof include 1,2-dimethylimidazole, 1-methylimidazole, 2-methylimidazole, 2-phenylimidazole, 1-phenylimidazole, imidazole and benzimidazole. The imidazole compound may be used in combination of two or more compounds. In an embodiment, the imidazole compound is preferably selected from imidazole compounds other than 1,2-dimethylimidazole, and is preferably a dimethyl-substituted imidazole compound other than 1,2-substituted compound, a monomethyl-substituted imidazole compound, and an aromatic-substituted imidazole compound, and particularly preferred are 2-phenylimidazole, 1-phenylimidazole, imidazole, and benzimidazole.

The content of the imidazole compound in the polyimide precursor composition may be appropriately selected in consideration of the balance between the addition effect and the stability of the polyimide precursor composition. When the imidazole compound is added, the amount (total content) is more than 0 mol per 1 mol of the repeating unit of the polyimide precursor, and in order to exert the addition effect to a certain extent, it is 0.01 mol or more, preferably 0.02 mol or more, while in terms of the viscosity stability of the polyimide precursor composition, it is preferably less than 1 mol, more preferably less than 0.8 mol. The addition of the imidazole compound is effective in improving the light transmittance and improving the adhesion under a long-term high-temperature environment such as annealing treatment.

In particular, when the ratio of the structure of formula (1-1) (derived from ODPA) in X₁ is less than 90 mol %, particularly less than 80 mol %, it is preferable to add an imidazole compound.

The imidazole compound can solve the problems when the ratio of the structure of formula (1-1) (derived from ODPA) in X₁ is small, or when the total ratio of the structure of formula (1-1) (derived from ODPA) and the structure of formula (1-2) (derived from s-BPDA) is small. When an imidazole compound is added, the ratio of the structure of formula (1-1) (derived from ODPA) in X₁ can be set to 0 mol % or more. In other words, as long as the total ratio of the structure of formula (1-1) and the structure of formula (1-2) in X₁ is 70 mol % or more, only one of them may be contained, for example, the ratio of the structure of formula (1-1) may be zero.

In summary, as defined in item 1. of Invention A Series, the present application discloses an embodiment in which an imidazole compound is not essential (condition (i)) and an embodiment in which an imidazole compound is essential (condition (ii)).

The present application also discloses the following other inventions, namely Invention B series, which require the addition of an imidazole compound.

A polyimide precursor composition comprising a polyimide precursor having a repeating unit represented by general formula (I), wherein
X₁ comprises a structure represented by formula (1-1) and/or a structure represented by formula (1-2) in an amount of 70 mol % or more (also preferably 80 mol % or more, or even 90 mol % or more),
Y₁ comprises a structure represented by formula (B) in an amount of 50 mol % or more (also preferably 80 mol % or more, or even 90 mol % or more), and
the polyimide precursor composition further comprises at least one imidazole compound in an amount of 0.01 mol or more and less than 1 mol per 1 mol of a repeating unit of the polyimide precursor.

In this other invention, elements and matters other than those specified above follow the description of Invention A Series in the main text of this application.

### <Silane Compound>

It is also preferable to add a silane compound having a Si—OR^{a} structure (wherein R^{a} is a hydrogen atom or a hydrocarbon group) (hereinafter, sometimes simply referred to as a “silane compound”) to the polyimide precursor composition as an additive. The addition of a silane compound is effective in improving light transmittance.

R^{a} is preferably a hydrocarbon group having 10 or less carbon atoms, preferably an alkyl group or an aryl group, particularly a straight-chain or branched alkyl group having 1 to 8 carbon atoms, more preferably 1 to 4 carbon atoms, and particularly preferably a methyl group or an ethyl group. The examples include a compound represented by (R^{a}O)ₙSi(R^{b})₄₋ₙ (n is an integer of 1 to 4). R^{a} is as described above, and n is preferably 1 to 3, more preferably 2 or 3. R^{b} is a hydrocarbon group having 10 or less carbon atoms, preferably an alkyl group or an aryl group, more preferably an aryl group, and particularly preferably a phenyl group.

Specific examples thereof include, methyltrimethoxysilane, methyltriethoxysilane, ethyltrimethoxysilane, ethyltriethoxysilane, hexyltrimethoxysilane, hexyltriethoxysilane, phenyltrimethoxysilane, phenyltriethoxysilane, dimethoxydimethylsilane, diethoxydimethylsilane, dimethoxydiphenylsilane, diethoxydiphenylsilane, tetramethoxysilane, tetraethoxysilane, tetrapropoxysilane, tetrabutoxysilane, tetraphenoxysilane, trimethylmethoxysilane, trimethylethoxysilane, triethylmethoxysilane, triethylethoxysilane, trihexylmethoxysilane, trihexylethoxysilane, triphenylmethoxysilane, and triphenylethoxysilane. The silane compounds may be used in combination of two or more.

The amount of the silane compound to be added can be appropriately selected in consideration of the effect of addition. When the silane compound is added, the amount (total content) is more than 0 parts by mass based on 100 parts by mass of the total of the tetracarboxylic acid component and the diamine component, and in order to exert a certain degree of the effect of addition, it is 0.05 parts by mass or more, preferably 0.1 parts by mass or more, more preferably 0.3 parts by mass or more, even more preferably 0.5 parts by mass or more, and even more preferably 1 part by mass or more. From the viewpoint of the balance of physical properties, it is, for example, 60 parts by mass or less, preferably 50 parts by mass or less, more preferably 40 parts by mass or less, even more preferably 35 parts by mass or less, even more preferably 30 parts by weight or less, and even more preferably 25 parts by weight or less.

### <Formulation of Polyimide Precursor Composition and “Polyimide Precursor Composition for Flexible Electronic Device Substrate”>

The polyimide precursor composition used in the present invention comprises at least one polyimide precursor as described above and preferably a solvent. As described above, it also preferably comprises at least one imidazole compound.

As the solvent, those mentioned above as the solvent used in preparing the polyimide precursor can be used. Generally, the solvent used in preparing the polyimide precursor may be used as it is, i.e., as the polyimide precursor solution as prepared. But, if necessary, it may be used after being diluted or concentrated. The imidazole compound (if added) is present dissolved in the polyimide precursor composition. Although the concentration of the polyimide precursor is not particularly limited, it is usually 5 to 45% by mass in terms of polyimide-converted mass concentration (solid content concentration). Here, the polyimide-converted mass is the mass when all repeating units are completely imidized.

Although the viscosity (rotational viscosity) of the polyimide precursor composition of the present invention is not limited thereto, the rotational viscosity, which is measured with an E-type rotational viscometer at a temperature of 25° C. and at a shearing speed of 20 sec⁻¹, may be preferably 0.01 to 1000 Pa-sec, more preferably 0.1 to 100 Pa-sec. In addition, thixotropy may be imparted, as necessary. When the viscosity is within the above-mentioned range, the composition is easy to handle during the coating or the film formation, and the varnish is less repelled and has excellent leveling property, and therefore a good film may be obtained.

The polyimide precursor composition of the present invention may comprise a chemical imidizing agent (an acid anhydride such as acetic anhydride, and an amine compound such as pyridine and isoquinoline), an anti-oxidizing agent, UV absorber, a filler (including an inorganic particle such as silica), a dye, a pigment, a coupling agent such as a silane coupling agent, a primer, a flame retardant, a defoaming agent, a leveling agent, a rheology control agent (flow-promoting agent), and the like, as necessary. When imidizing the polyimide precursor composition of the present invention, thermal imidization is preferred, and in this case, it is preferable not to contain an acid anhydride such as acetic anhydride, which is a chemical imidization agent.

The polyimide precursor composition can be prepared by adding and mixing an imidazole compound or a solution of an imidazole compound to the polyimide precursor solution obtained by the method described above. Alternatively, in the presence of an imidazole compound, the tetracarboxylic acid component and the diamine component may be reacted.

The polyimide precursor composition of the present invention can be used “for flexible electronic device substrates (particularly preferably flexible display substrates; the same applies below)”. As described above, in the present invention, the polyimide precursor composition “for flexible electronic device substrates” refers to one that is directly applied onto a substrate, as will be described below.

### <<Manufacturing of Polyimide Film/Substrate Laminate and Flexible Electronic Device>>

A polyimide film/substrate laminate can be produced using the polyimide precursor composition of the present invention (i.e., polyimide precursor composition for flexible electronic device substrates). The polyimide film/substrate laminate is produced by (a) applying the polyimide precursor composition onto a substrate; (b) heat-treating the polyimide precursor on the substrate to form a laminate in which the polyimide film is laminated on the substrate (polyimide film/substrate laminate). In addition, it is also preferable to further include a step (b2) of forming an inorganic thin film on the surface of the polyimide film after forming a polyimide film on the substrate.

A method of manufacturing a flexible electronic device, of the present invention comprises, using the polyimide film/substrate laminate produced above step (a) and step (b), further steps of (c) forming at least one layer selected from a conductor layer and a semiconductor layer on the polyimide film of the laminate; and (d) separating the substrate and the polyimide film.

First, in step (a), a polyimide precursor composition is cast on a substrate, imidized and desolvated by heat treatment to form a polyimide film, to obtain a laminate of the substrate and the polyimide film (polyimide film/substrate laminate).

As the substrate, a heat-resistant material is used. For example, a plate-like or a sheet-like substrate of, for example, ceramic materials (glass, alumina, and the like), metal materials (iron, stainless steel, copper, aluminum, and the like), semiconductor materials (silicon, compound semiconductors, and the like), or a film or sheet-like substrate of heat-resistant plastic materials (polyimide and the like) may be used. In general, a flat and smooth plate shape is preferable, and glass substrates of soda lime glass, borosilicate glass, alkali-free glass, sapphire glass, and the like; semiconductor (including compound semiconductors) substrates of silicon, GaAs, InP, GaN and the like; metal substrates of iron, stainless steel, copper, aluminum and the like are generally used.

A glass substrate is particularly preferable as the substrate. Glass substrates that are flat, smooth, and have a large area have been developed and are readily available. The thickness of the plate-like substrate such as a glass substrate is not limited, but from the viewpoint of ease of handling, it is, for example, 20 m to 4 mm, preferably 100 m to 2 mm. The size of the plate-like substrate is not particularly limited, but one side (long side in the case of a rectangle) is, for example, about 100 mm to 4000 mm, preferably about 200 mm to 3000 mm, more preferably about 300 mm to 2500 mm.

These substrates such as glass substrates may have an inorganic thin film (for example, a silicon oxide film) or a resin thin film formed on the surface thereof.

The method of casting the polyimide precursor composition onto the substrate is not particularly limited, and examples thereof include slit coating, die coating, blade coating, spray coating, inkjet coating, nozzle coating, spin coating, and screen printing method, bar coater method, electrodeposition method, and other conventionally known methods.

In step (b), the polyimide precursor composition is heat-treated on the substrate to convert it into a polyimide film to obtain a polyimide film/substrate laminate. The heat treatment conditions are not particularly limited. For example, it is preferred that after drying in a temperature range of 50° C. to 150° C., the film is processed such that the maximum heating temperature is, for example, 150° C. to 600° C., preferably 200° C. to 550° C., more preferably 250° C. to 500° C.

The thickness of the polyimide film is preferably 1 m or more, more preferably 2 m or more, and further more preferably 5 m or more. If the thickness is less than 1 m, the polyimide film cannot maintain sufficient mechanical strength, and when used as a flexible electronic device substrate, for example, it may not withstand stress and break. Also, the thickness of the polyimide film is preferably 100 m or less, more preferably 50 m or less, and further more preferably 20 m or less. When the thickness of the polyimide film increases, it may become difficult to reduce the thickness of the flexible device. The thickness of the polyimide film is preferably 2 to 50 m in order to make it thinner while maintaining sufficient resistance as a flexible device.

In the present invention, it is preferable that the polyimide film/substrate laminate has a small warp. The properties of the polyimide film can be evaluated by the residual stress between the polyimide film and the silicon substrate in the polyimide film/silicon substrate (wafer) laminate. The residual stress that can be achieved by the present invention will be described later.

The polyimide film in the polyimide film/substrate laminate may have a second layer such as an inorganic thin film on the surface, and therefore, as step (b2), it is preferable to have a step of forming an inorganic thin film on the surface of the polyimide film formed on the substrate. The inorganic thin film is preferably one that functions as a barrier layer against water vapor, oxygen (air), and the like. Examples of the water vapor barrier layer include inorganic thin films containing an inorganic material selected from the group consisting of metal oxides, metal nitrides and metal oxynitrides such as silicon nitride (SiNₓ), silicon oxide (SiOₓ), silicon oxynitride (SiOₓN_{y}), aluminum oxide (Al₂O₃), titanium oxide (TiO₂), and zirconium oxide (ZrO₂). Generally, as methods of forming these thin films, physical vapor deposition methods such as vacuum vapor deposition method, sputtering method and ion plating method, and chemical vapor deposition (CVD; chemical vapor deposition) methods such as plasma CVD method and catalytic chemical vapor deposition (Cat-CVD) method and the like are known. In these film formation methods, including the CVD method, high-temperature annealing is performed, for example at 350° C. to 450° C., after film formation to densify the film in order to improve the barrier function. In this application, the term “inorganic thin film” refers to both of the films in the state before and after annealing. If it means only one of the two states, it is explicitly indicated or is clear from the context. Similarly, the term “polyimide film/substrate laminate” refers to both of those with or without the “inorganic thin film”.

The second layer may be a multi-layer structure. In this case, different types of inorganic thin films may be formed, or a resin film and an inorganic thin film may be combined. An example of the latter is a three-layer structure of a barrier layer/polyimide layer/barrier layer formed on the polyimide film in a polyimide film/substrate laminate.

In step (c), using the polyimide/substrate laminate obtained in step (b), on a polyimide film (including a second layer such as an inorganic thin film laminated on the surface of the polyimide film), at least one layer selected from a conductor layer and a semiconductor layer is formed. These layers may be formed directly on the polyimide film (including the lamination of the second layer) or may be formed on the surface of the other deposited (laminated) layers required for the device, namely, indirectly on the polyimide film.

For the conductor layer and/or the semiconductor layer, an appropriate conductor layer and (inorganic or organic) semiconductor layer are selected according to the elements and circuits required by the intended electronic device. When forming at least one of the conductor layer and the semiconductor layer in the step (c) of the present invention, it is also preferable to form at least one of the conductor layer and the semiconductor layer on the polyimide film on which the inorganic film has been formed.

The conductor layer and the semiconductor layer include both those formed on the entire surface of the polyimide film and those formed on a part of the polyimide film. In the present invention, step (d) may be performed immediately after step (c), or after forming at least one layer selected from a conductor layer and a semiconductor layer in step (c) and after further device structure(s) is formed after step (c), the step (d) may be performed.

When manufacturing a TFT liquid crystal display device as a flexible device, for example, a metal wiring, a TFT made of amorphous silicon or polysilicon, and a transparent pixel electrode are formed on a polyimide film on which an inorganic film is formed on the entire surface if necessary. A TFT includes, for example, a gate metal layer, a semiconductor layer such as an amorphous silicon film, a gate insulating layer, wiring connected to a pixel electrode, and the like. On top of this, a structure necessary for a liquid crystal display can also be formed by a known method. Also, a transparent electrode and a color filter may be formed on the polyimide film.

When manufacturing an organic EL display, for example, a transparent electrode, a light-emitting layer, a hole-transporting layer, an electron-transporting layer, and the like and a TFT as necessary are formed on a polyimide film on which an inorganic film is formed on the entire surface if necessary.

Since the polyimide film preferred in the present invention is excellent in various properties such as heat resistance and toughness, there are no particular restrictions on the method of forming the circuits, elements and other structures necessary for the device.

Next, in step (d), the substrate and the polyimide film are separated. The peeling method may be a mechanical peeling method of physically peeling by applying an external force, but since the polyimide film/substrate laminate of the present invention has excellent adhesion, particularly preferred is a so-called laser peeling method in which laser light is irradiated from the substrate surface to effect peeling.

After peeling off the substrate, a device is completed by forming or incorporating a structure or parts necessary for the device into a (semi-) product having the polyimide film as a substrate.

As described above, a flexible electronic device including a polyimide film is completed, and in the flexible electronic device, the polyimide film functions as a flexible electronic device substrate.

As a different method for producing a flexible electronic device, after a polyimide film/substrate laminate by the above step (b) is produced and then the polyimide film is peeled off, a (semi-) product using a polyimide film as a substrate is produced by forming at least one layer selected from a conductor layer and a semiconductor layer, and necessary structures.

### <<Properties of Polyimide Film in Polyimide Film/Substrate Laminate>>

If the above-described polyimide film/substrate laminate is produced from the polyimide precursor composition of the present invention, the adhesion between the polyimide film and the substrate is excellent, and therefore, it is particularly preferable that the polyimide precursor composition is used for this purpose.

The ranges of the properties of the polyimide film achieved by the present invention are described below, in which the preferred ranges will be listed by order of first range, second range, third range, . . . , nth range with the latter more preferable.

A polyimide film produced from the polyimide precursor composition of the present invention has excellent optical transparency, thermal properties, and heat resistance, as well as excellent adhesion to substrates such as glass substrates.

The adhesion can be evaluated by peel strength. When the peel strength between the polyimide film and the substrate in the polyimide film/substrate laminate is measured in accordance with JIS K6854-1, for example, in a tensile speed of 2 mm/min and a 900 peel test, it is preferably 50 gf/cm (0.49 N/cm) or more (first range), and is more preferably 100 gf/cm (0.98 N/cm) or more (second range), 150 gf/cm (1.47 N/cm) or more (third range), 200 gf/cm (1.96 N/cm) or more (fourth range), 300 gf/cm (2.94 N/cm) or more (fifth range), 400 gf/cm (3.92 N/cm) or more (sixth range), and 500 gf/cm (4.9 N/cm) or more (seventh range) in this order. The upper limit is usually 5 kgf/cm (49.0 N/cm) or less, preferably 3 kgf/cm (29.4 N/cm) or less. The peel strength is usually measured in air or in the atmosphere.

As mentioned above, it is preferable that the polyimide film/substrate laminate has small warpage, and the properties of the polyimide film can be evaluated by the residual stress between the polyimide film and the silicon substrate in the polyimide film/silicon substrate (wafer) laminate. The details of the measurement are described in Japanese Patent No. 6798633. Herein, the polyimide film is assumed to be placed at 23° C. in a dry state. The residual stress evaluated by this method is preferably 20 MPa or less (first range), and more preferably 15 MPa or less (second range), 12 MPa or less (third range), and 10 MPa or less (fourth range) in this order.

In one embodiment of the present invention, when measured on a film having a thickness of 10 m, the 450 nm light transmittance of the polyimide film is preferably 73% or more (first range), and is furthermore preferably, 74% or more (second range), and 75% or more (third range) in this order. When measured on a film having a thickness of 10 m, the yellowness index (YI) of the polyimide film is preferably 13 or less (first range), and is furthermore preferably 12 or less (second range), 11 or less (third range), 10 or less (fourth range), and 9 or less (fifth range) in this order. The yellowness index (YI) is preferably 0 or more. Furthermore, when measured on a film having a thickness of 10 m, the haze value of the polyimide film is preferably less than 1.0% (first range), and is furthermore preferably 0.9% or less (second range), 0.8% or less (third range), 0.7% or less (fourth range), and 0.6% or less (fifth range) in this order.

The polyimide film of the present invention has an extremely low coefficient of linear thermal expansion (CTE). In one embodiment of the present invention, when measured on a film having a thickness of 10 m, the coefficient of linear thermal expansion of the polyimide film from 150° C. to 250° C. is preferably 27 ppm/K or less (first range), is furthermore preferably 25 ppm/K or less (second range), 20 ppm/K or less (third range), 15 ppm/K or less (fourth range), and 13 ppm/K or less (fifth range) in this order.

The polyimide film of the present invention (or the polyimide constituting the polyimide film) has excellent heat resistance, and the 1% weight loss temperature is preferably 512° C. or higher (first range), and is furthermore preferably 515° C. or higher (second range), 520° C. or higher (third range), and 522° C. or higher (fourth range) in this order.

In one embodiment of the present invention, the glass transition temperature (Tg) of the polyimide film (or the polyimide constituting the polyimide film) is preferably 350° C. or higher, more preferably 370° C. or higher, even more preferably 390° C. or higher, even more preferably 400° C. or higher, even more preferably 410° C. or higher, even more preferably 420° C. or higher, even more preferably 430° C. or higher, even more preferably 435° C. or higher, and most preferably 440° C. or higher.

The polyimide film of the present invention exhibits a very large elastic modulus. In one embodiment of the present invention, the elastic modulus of the polyimide film is preferably 6.5 GPa or more (first range), and is furthermore preferably 6.9 GPa or more (second range), 7.3 GPa or more (third range), 7.5 GPa or more (fourth range), 7.6 GPa or more (fifth range), 8.0 GPa or more (sixth range), and 8.3 GPa or more (seventh range) in this order. The elastic modulus can be, for example, a value obtained from a film having a thickness of about 8 to 12 m.

Furthermore, in one embodiment of the present invention, the elongation at break of the polyimide film, when measured on a film having a thickness of 10 m, is preferably 10% or more (first range), and is furthermore preferably 20% or more (second range), 25% or more (third range), and 30% or more (fourth range) in this order.

In another preferred embodiment of the present invention, the breaking strength of the polyimide film is preferably 200 MPa or more (first range), and is furthermore preferably 250 MPa or more (second range), 270 MPa or more (third range), and 300 MPa or more (fourth range) in this order. The breaking strength can be, for example, a value obtained from a film having a thickness of about 5 to 100 m.

Regarding the properties of the polyimide film, it is preferable that the adhesion, light transmittance, and elastic modulus simultaneously satisfy the “preferred ranges,” and it is particularly preferable that the coefficient of linear thermal expansion and 1% weight loss temperature also simultaneously satisfy the “preferred ranges.”

A polyimide film having such properties, i.e., a polyimide film for flexible electronic device substrates, is novel in itself and independently patentable. Particularly preferred embodiments are as follows.
(1) The polyimide film has a 450 nm light transmittance of 74% or more (second range), an elastic modulus of 6.9 GPa or more (second range), preferably 7.3 GPa or more (third range), and a coefficient of linear thermal expansion and an elongation at break that satisfy the above-mentioned first range.
(2) The polyimide film has a 450 nm light transmittance of 75% or more (third range), preferably 76% (fourth range), a modulus of elasticity of 7.3 GPa or more (third range), and a coefficient of linear thermal expansion and elongation at break satisfy the above-mentioned first range.
(3) The polyimide film has a 450 nm light transmittance of 74% or more (second range), preferably 75% or more (third range), and the peel strength between the polyimide film and the substrate in the polyimide film/substrate laminate is 200 gf/cm or more (fourth range), preferably 300 gf/cm or more (fifth range).

The polyimide precursor composition of the present invention may be used to produce other forms of polyimide and a single polyimide film. The production method is not particularly limited, and any known imidization method may be suitably applied. Suitable forms of the obtained polyimide include a film, a coating film, a powder, beads, a molded product, a foam, and the like.

A single polyimide film may be produced by a known method. A typical method comprises casting a polyimide precursor composition onto a substrate, and heat imidizing the composition on the substrate, and then peeling off the polyimide film. Alternatively, a polyimide film can be obtained by casting a polyimide precursor composition onto a substrate, heating and drying the composition to produce a self-supporting film, peeling the self-supporting film from the substrate, and heat imidizing the film in a state in which degassing is possible from both sides of the film, for example, by holding the film with a tenter.

The thickness of a single polyimide film varies depending on the application, but is preferably 1 m or more, more preferably 2 m or more, and even more preferably 5 m or more, and is, for example, 250 m or less, preferably 150 m or less, more preferably 100 m or less, and even more preferably 50 m or less.

### EXAMPLES

The present invention will be further described below with reference to Examples and Comparative Examples. However, the present invention is not limited to the Examples as described below.

In each of the Examples as described below, the evaluations were conducted by the following methods.

### <<Evaluation of Polyimide Precursor Composition>>

### [Evaluation of Viscosity Stability and Maximum Viscosity Holding]

After polymerization, when the polyimide precursor composition is stored at 23° C., the viscosity increases and reaches a maximum viscosity, and then starts to decrease. When the maximum viscosity is reached, it is evaluated as “viscosity has reached stable state”. In addition, the viscosity decreases after reaching the maximum viscosity, and the ratio of the viscosity 30 days after the day the maximum viscosity is reached to the maximum viscosity is evaluated as “maximum viscosity holding ratio”. If the viscosity is 50% or more of the maximum viscosity, it is evaluated as “∘ (good),” and if the viscosity is less than 50%, it is evaluated as “x (bad)”.

The viscosity was measured at a temperature of 25° C. using an E-type viscometer TVE-25 manufactured by Toki Sangyo Co., Ltd.

### <Evaluation of Polyimide Film>

### [450 nm Light Transmittance]

The light transmittance at 450 nm was measured using a UV-Visible Spectrophotometer/V-650DS (manufactured by JASCO Corporation) using the polyimide film having a thickness of about 10 m for the Examples and Comparative Examples where no thickness was stated, and using the polyimide film having the thickness as stated where a thickness was stated.

### [Yellow Index (YI)]

b* (=YI; yellow index) of the polyimide film having a thickness of 10 m and a size of 5 cm square was measured in accordance with the ASTM E313 standard using an ultraviolet-visible spectrophotometer/V-650DS (manufactured by JASCO Corporation). The light source was D65 and the viewing angle was 2°.

### [Haze]

The haze of the polyimide film was measured using a turbidity meter/NDH2000 (manufactured by Nippon Denshoku Industries Co., Ltd.) in accordance with the standard of JIS K7136.

### [Coefficient of Linear Thermal Expansion (CTE)]

A polyimide film with a thickness of about 10 m was cut into a strip with a width of 4 mm to prepare a test piece, and the test piece was cooled from 400° C. to 50° C. using a TMA/SS6100 (manufactured by SII Nano Technology Co., Ltd.) with a chuck length of 15 mm, a load of 2 g, and a temperature drop rate of 20° C./min. The coefficient of linear thermal expansion from 150° C. to 250° C. was determined from the obtained TMA curve.

### [1% Weight Loss Temperature]

The polyimide film having a thickness of about 10 μm was used as a test piece, and the test piece was heated from 25° C. to 600° C. at a temperature-increasing rate of 10° C./min in a flow of nitrogen using a thermogravimetric measuring apparatus (Q5000IR) made by TA Instruments Inc. The 1% weight loss temperature was determined from the obtained weight curve taking the weight at 150° C. as 100%.

### [Peel Strength]

The peel strength in the 900 direction was measured in air at a pulling speed of 2 mm/min using a TENSILON RTA-500 manufactured by Orientec Co., Ltd.

### [Measurement of Residual Stress]

A 6-inch silicon wafer (625 m thick, (100) substrate) was used as a reference substrate for evaluating the polyimide film. The polyimide precursor composition was applied onto the silicon wafer by a spin coater, and the composition was heated directly on the silicon wafer in a nitrogen atmosphere (oxygen concentration 200 ppm or less) from room temperature to the same temperature as in the Examples and Comparative Examples to thermally imidize the composition, thereby obtaining a polyimide film/reference substrate laminate. The thickness of the polyimide film in the laminate was approximately 10 km.

According to the description of Japanese Patent No. 6798633, the radius of curvature of the warp of the obtained polyimide film/silicon wafer laminate is measured at temperatures of 150° C., 140° C., 130° C., 120° C. and 110° C. using a FLX-2320 manufactured by KLA Tencor Corporation. 20 measurements are made at each temperature and the average value is calculated. The radius of curvature of the silicon wafer alone is also measured at the same temperature. From the obtained radius of curvature, the residual stress (S) at each temperature is calculated according to the following Equation 1, and the residual stress at 23° C. is calculated from a linear approximation by the least squares method.

$$S = \frac{{Eh}^{2}}{( 1 - v ) 6 Rt} \qquad Equation 1$$

wherein
E/(1−ν): biaxial elastic modulus (Pa) of substrate (reference substrate: silicon wafer),
   for (100) silicon, it is 1.805E11 Pa.
h: thickness of the substrate (m)
t: thickness of polyimide film (m)
R: radius of curvature of the measurement sample (m)

$$1 / R = 1 / {R}_{2} - 1 / {R}_{1}$$

R₁: Radius of curvature of the substrate (silicon wafer) alone before film formation
   R₂: Radius of curvature after film formation
S: average residual stress (Pa)

### [Elastic Modulus, Elongation at Break, Breaking Strength]

A polyimide film having a thickness of about 10 m was punched into a dumbbell shape according to the IEC 450 standard to prepare a test piece, and the initial elastic modulus, elongation at break, and breaking strength were measured using a TENSILON manufactured by ORIENTEC Corporation at a chuck distance of 30 mm and a tensile speed of 2 mm/min.

### <Raw Materials>

The abbreviations for the raw materials used in the following examples are as follows:

### [Tetracarboxylic Acid Component]

PMDA: pyromellitic dianhydride
DSDA: 3,3′,4,4′-biphenyltetracarboxylic dianhydride
ODPA: 4,4′-oxydiphthalic dianhydride
s-BPDA: 3,3′,4,4′-biphenyltetracarboxylic dianhydride
6FDA: 2,2-bis(3,4-dicarboxyphenyl)hexafluoropropane dianhydride

### [Diamine Component]

4-BAAB: 4-aminophenyl-4-aminobenzoate
BAPB: 4,4′-bis(4-aminophenoxy)biphenyl
4,4-ODA: 4,4-oxydianiline

### [Imidazole Compound]

2-Pz: 2-phenylimidazole
Bz: benzimidazole
Im: imidazole
1-Pz: 1-phenylimidazole
KBM-103: phenyltrimethoxysilane (manufactured by Shin-Etsu Chemical Co., Ltd.)
KBM-202SS: Diphenyldimethoxysilane (manufactured by Shin-Etsu Chemical Co., Ltd.)
HIVAC-F-5: 1,3,5-trimethyl-1,1,3,5,5-pentaphenyltrisiloxane (manufactured by Shin-Etsu Chemical Co., Ltd.)

### [Solvent]

NMP: N-methyl-2-pyrrolidone

Table 1-1 shows the structural formulas of the tetracarboxylic acid component and the diamine component, and Table 1-2 shows the structural formula of the imidazole compound.

TABLE 1-1

| Tetracarboxylic acid | |
|---|---|
| dianhydride | Diamine |
| 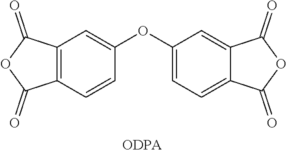 [SMILES: O=C1OC(=O)c2cc(Oc3ccc4c(c3)C(=O)OC4=O)ccc21] | 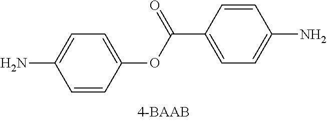 [SMILES: Nc1ccc(OC(=O)c2ccc(N)cc2)cc1] |
| 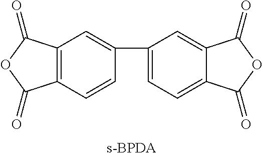 [SMILES: O=C1OC(=O)c2cc(-c3ccc4c(c3)C(=O)OC4=O)ccc21] | 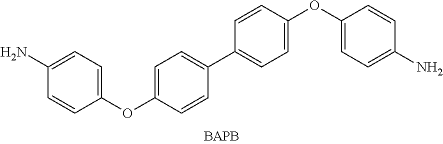 [SMILES: Nc1ccc(Oc2ccc(-c3ccc(Oc4ccc(N)cc4)cc3)cc2)cc1] |
| 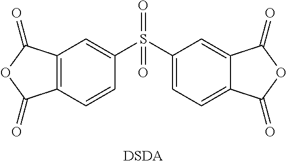 [SMILES: O=C1OC(=O)c2cc(S(=O)(=O)c3ccc4c(c3)C(=O)OC4=O)ccc21] | 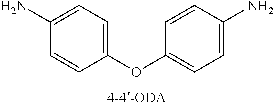 [SMILES: Nc1ccc(Oc2ccc(N)cc2)cc1] |
| 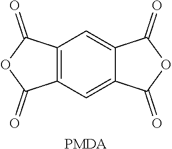 | |
| 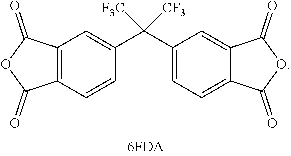 [SMILES: O=C1OC(=O)c2cc(C(c3ccc4c(c3)C(=O)OC4=O)(C(F)(F)F)C(F)(F)F)ccc21] | |

TABLE 1-2
Imidazole compound

| | | | |
|---|---|---|---|
| 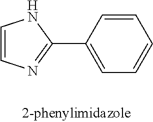 [SMILES: c1ccc(-c2ncc[nH]2)cc1] | 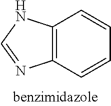 | 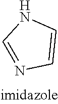 | 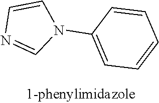 [SMILES: c1ccc(-n2ccnc2)cc1] |

TABLE 1-3
Silane compound

| | | |
|---|---|---|
| 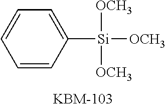 [SMILES: CO[Si](OC)(OC)c1ccccc1] | 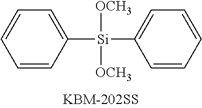 [SMILES: CO[Si](OC)(c1ccccc1)c1ccccc1] | 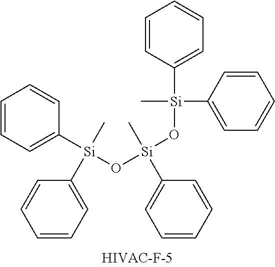 [SMILES: C[Si](O[Si](C)(c1ccccc1)c1ccccc1)(O[Si](C)(c1ccccc1)c1ccccc1)c1ccccc1] |

### Example 1

### [Preparation of Polyimide Precursor Composition]

Into a reaction vessel purged with nitrogen gas, 2.28 g (10 mmol) of 4-BAAB was charged and N-methyl-2-pyrrolidone was added in an amount of 37.69 g such that the total mass of the charged monomers (the sum of the diamine component and the carboxylic acid component) becomes 12.5% by mass, and the mixture was stirred at room temperature for 1 hour. To this solution, 3.10 g (10 mmol) of ODPA was gradually added. After stirring at room temperature for 6 hours, a uniform and viscous polyimide precursor solution was obtained. The viscosity stability of the polyimide precursor composition is shown in Table 2.

[Production of polyimide film/substrate laminate]

As a glass substrate, a 6-inch Eagle-XG (registered trademark) (500 m thick) manufactured by Corning was used. A polyimide precursor composition is applied onto a glass substrate by a spin coater, and under a nitrogen atmosphere (oxygen concentration of 200 ppm or less), the glass substrate is heated from room temperature to 420° C. to thermally imidize, thereby a polyimide film/substrate laminate was obtained. As for the peel strength, from the obtained polyimide film/glass laminate, a test sample having a width of 5 mm was made and used for measurement. As for other film properties, the laminate was immersed in water at 40° C. (eg. temperature range of 20° C. to 100° C.) to separate the polyimide film from the glass substrate, and after drying, the properties of the polyimide film were evaluated. The film thickness of the polyimide film is about 10 m. Table 2 shows the evaluation results.

### Examples 2 to 6, Comparative Examples 1 to 4

A polyimide precursor composition was obtained in the same manner as in Example 1, except that the tetracarboxylic acid component and the diamine component were changed to the compounds and amounts (molar ratios) shown in Table 2. Thereafter, a polyimide film was produced in the same manner as in Example 1, and the physical properties of the film were evaluated.

### Examples 7, 11, Comparative Examples 6 to 8

In Example 1, the tetracarboxylic acid component and the diamine component were changed to the compounds and amounts (molar ratios) shown in Table 3, and a polyimide precursor composition was obtained by reacting in the same manner as in Example 1. Using the obtained polyimide precursor composition, a polyimide film was produced in the same manner as in Example 1, except that the maximum heating temperature for imidization was changed to 450° C., and the physical properties of the film were evaluated.

### Examples 8 to 10, Comparative Example 5

In Example 1, the tetracarboxylic acid component and the diamine component were changed to the compounds and amounts (molar ratios) shown in Table 3, and a polyimide precursor composition was obtained by reacting in the same manner as in Example 1.

2-Phenylimidazole as an imidazole compound was dissolved in four times the mass of N-methyl-2-pyrrolidone to obtain a uniform solution having a solid concentration of 20% by mass of 2-phenylimidazole. The imidazole compound solution and the polyimide precursor solution synthesized above are mixed so that the amount of the imidazole compound per 1 mol of the repeating unit of the polyimide precursor was the amount shown in Table 3, and the mixture was stirred at room temperature for 3 hours to obtain a homogeneous and viscous polyimide precursor composition.

Thereafter, a polyimide film was produced and its physical properties were evaluated in the same manner as in Example 7. However, in Comparative Example 5, since the viscosity stability of the obtained polyimide precursor composition was poor, it was difficult to form a uniform polyimide film on the substrate, and therefore the film properties could not be evaluated.

### Examples 12 to 25, Comparative Examples 9, 10

In Example 1, the tetracarboxylic acid component and the diamine component were changed to the compounds and amounts (molar ratios) shown in Table 4 or 5, and a polyimide precursor composition was obtained by reacting in the same manner as in Example 1.

The imidazole compound was changed to a compound shown in Table 4 or 5, and the solution of the imidazole compound and the polyimide precursor solution synthesized above were mixed so that the amount of the imidazole compound was the amount shown in Table 4 or 5. The mixture was stirred at room temperature for 3 hours to obtain a homogeneous and viscous polyimide precursor composition.

Thereafter, a polyimide film was produced and its physical properties were evaluated in the same manner as in Example 1, except that the maximum heating temperature for imidization was 420° C. or 450° C. (as shown in Tables 4 and 5). In Comparative Example 9, no imidazole compound was added.

Examples belonging to the condition (i) and the condition (ii) defined in 1. of the Invention A Series of the present application are listed as follows.
(i) 1-6, 7-11, 15-18, 19-25, 28
(ii) 8-10, 12-18, 19-25, 26, 27, 28

TABLE 2

| | | Example | Example | Example | Example | Example | Example | Comp-Ex | Comp-Ex | Comp-Ex | Comp-Ex |
|---|---|---|---|---|---|---|---|---|---|---|---|
| | | 1 | 2 | 3 | 4 | 5 | 6 | 1 | 2 | 3 | 4 |
| Acid | ODPA | 100 | 80 | 60 | 50 | 50 | 50 | 40 | 20 | | 50 |
| dianhydride | s-BPDA | | 20 | 40 | 50 | 50 | 50 | 60 | 80 | 100 | 50 |
| | 6FDA | | | | | | | | | | |
| | DSDA | | | | | | | | | | |
| | PMDA | | | | | | | | | | |
| Diamine | 4-BAAB | 100 | 100 | 100 | 100 | 80 | 80 | 100 | 100 | 100 | 60 |
| | BAPB | | | | | 20 | | | | | |
| | 4,4-ODA | | | | | | 20 | | | | 40 |
| Imidazole | 2-Pz | | | | | | | | | | |
| compound | | | | | | | | | | | |

| | | | | | | | | | | |
|---|---|---|---|---|---|---|---|---|---|---|
| Cure temperature / ° C. | 420 | 420 | 420 | 420 | 420 | 420 | 420 | 420 | 420 | 420 |
| Evaluation of Varnish | | | | | | | | | | |
| viscosity stability | ∘ | ∘ | ∘ | ∘ | ∘ | ∘ | ∘ | ∘ | ∘ | — |
| Evaluation of Film | | | | | | | | | | |
| Elastic modulus / GPa | 8.5 | 9.1 | 8.8 | 9.3 | 7.1 | 7.0 | 9.5 | 9.2 | 9.3 | 6.2 |
| Elongation at break / % | 25 | 23 | 27 | 23 | 34 | 35 | 27 | 33 | 17 | 42 |
| Breaking strength / MPa | 356 | 389 | 450 | 405 | 400 | 425 | 470 | 477 | 373 | 375 |
| CTE /ppm · K−1 | 20 | 12 | 7 | 5 | 15 | 13 | 7 | 5 | 4 | 30 |
| 1 wt % weight loss | 520 | 522 | 524 | 525 | 526 | 525 | 527 | 529 | 533 | 519 |
| temperature / ° C. | | | | | | | | | | |
| Light transmittance | 78 | 77 | 76 | 75 | 75 | 75 | 73 | 72 | 72 | 75 |
| at 450 nm / % | | | | | | | | | | |
| YI | 9 | 10 | 11 | 12 | 12 | 12 | 15 | 16 | 16 | 12 |
| Haze / % | 0.3 | 0.2 | 0.2 | 0.3 | 0.5 | 0.5 | 0.2 | 0.2 | 0.2 | 1.3 |
| Evaluation of glass laminate | | | | | | | | | | |
| Peel strength /gf · cm−1 | >400 | >400 | >400 | >400 | >400 | >400 | 250 | 150 | 50 | >400 |
| Evaluation of silicon | | | | | | | | | | |
| wafer laminate | | | | | | | | | | |
| Residual stress / MPa | 11 | 9 | <4 | <4 | 14 | 11 | <4 | <4 | <4 | 25 |
| Evaluation of | | | | | | | | | | |
| SiO/SiN laminate | | | | | | | | | | |
| Adhesion test | ∘ | ∘ | ∘ | ∘ | ∘ | ∘ | ∘ | ∘ | ∘ | ∘ |

The amount of the imidazole compound is expressed in units of eq (mol per 1 mol of repeating unit).
Comp-Ex: Comparative Example

TABLE 3

| | | Example | Example | Example | Example | Example | Comp-Ex | Comp-Ex | Comp-Ex | Comp-Ex |
|---|---|---|---|---|---|---|---|---|---|---|
| | | 7 | 8 | 9 | 10 | 11 | 5 | 6 | 7 | 8 |
| Acid dianhydride | ODPA | 70 | 70 | 70 | 70 | 50 | 70 | 50 | 60 | |
| | s-BPDA | 30 | 30 | 30 | 30 | 30 | 30 | 10 | | 70 |
| | 6FDA | | | | | 20 | | 40 | | |
| | DSDA | | | | | | | | | 30 |
| | PMDA | | | | | | | | 40 | |
| Diamine | 4-BAAB | 100 | 100 | 100 | 100 | 100 | 100 | 100 | 100 | 100 |
| | BAPB | | | | | | | | | |
| | 4,4-ODA | | | | | | | | | |
| Imidazole | 2-Pz | | 0.025 | 0.1 | 0.5 | | 1 | | | |
| compound | | | | | | | | | | |

| | | | | | | | | | |
|---|---|---|---|---|---|---|---|---|---|
| Cure temperature / ° C. | 450 | 450 | 450 | 450 | 450 | | 450 | 450 | 450 |
| Evaluation of Varnish | | | | | | | | | |
| viscosity stability | ∘ | ∘ | ∘ | ∘ | ∘ | x | ∘ | ∘ | ∘ |
| Evaluation of Film | | | | | | | | | |
| Elastic modulus / GPa | 9.4 | 8.1 | 7.6 | 6.9 | 8.2 | — | 5.8 | 8.3 | 6.1 |
| Elongation at break / % | 33 | 37 | 51 | 59 | 22 | — | 29 | 38 | 22 |
| Breaking strength / MPa | 474 | 444 | 438 | 332 | 353 | — | 245 | 454 | 273 |
| CTE /ppm · K−1 | 7 | 13 | 19 | 27 | 10 | — | 29 | 17 | 27 |
| 1 wt % weight loss temperature / ° C. | 527 | 529 | 529 | 524 | 512 | — | 499 | 521 | 504 |
| Light transmittance at 450 nm / % | 74 | 77 | 77 | 75 | 74 | — | 74 | 69 | 71 |
| YI | 13 | 10 | 10 | 12 | 13 | — | 14 | 20 | 18 |
| Haze / % | 0.3 | 0.3 | 0.3 | 0.3 | 0.5 | — | 1.2 | 0.4 | 0.7 |
| Evaluation of glass laminate | | | | | | | | | |
| Peel strength /gf · cm−1 | >400 | >400 | >400 | >400 | >400 | — | 50 | >400 | 200 |
| Evaluation of silicon wafer laminate | | | | | | | | | |
| Residual stress / MPa | <4 | 10 | 12 | 20 | 7 | — | 23 | 18 | 22 |
| Evaluation of SiO/SiN laminate | | | | | | | | | |
| Adhesion test | ∘ | ∘ | ∘ | ∘ | ∘ | — | x | ∘ | x |

The amount of the imidazole compound is expressed in units of eg (mol per 1 mol of repeating unit).

TABLE 4

| | | Example | Example | Comp-Ex | Example | Example | Example | Example | Example |
|---|---|---|---|---|---|---|---|---|---|
| | | 12 | 13 | 9 | 14 | 15 | 16 | 17 | 18 |
| Acid dianhydride | ODPA | | 30 | 30 | 40 | 50 | 60 | 80 | 100 |
| | s-BPDA | 100 | 70 | 70 | 60 | 50 | 40 | 20 | |
| | 6FDA | | | | | | | | |
| | DSDA | | | | | | | | |
| | PMDA | | | | | | | | |
| Diamine | 4-BAAB | 100 | 100 | 100 | 100 | 100 | 100 | 100 | 100 |
| | BAPB | | | | | | | | |
| | 4,4-ODA | | | | | | | | |
| Imidazole | 2-Pz | 0.025 | 0.025 | | 0.025 | 0.025 | 0.025 | 0.025 | 0.025 |
| compound | Bz | | | | | | | | |
| | Im | | | | | | | | |
| | 1-Pz | | | | | | | | |

| | | | | | | | | |
|---|---|---|---|---|---|---|---|---|
| Cure temperature / ° C. | 420 | 420 | 420 | 420 | 420 | 420 | 420 | 420 |
| Evaluation of Varnish | | | | | | | | |
| viscosity stability | ∘ | ∘ | ∘ | ∘ | ∘ | ∘ | ∘ | ∘ |
| Evaluation of Film | | | | | | | | |
| Elastic modulus / GPa | 8.9 | 8.6 | 9.7 | 9.3 | 9.2 | 9.1 | 8.9 | 7.4 |
| Elongation at break / % | 40 | 44 | 30 | 46 | 40 | 31 | 30 | 43 |
| Breaking strength / MPa | 482 | 527 | 473 | 535 | 484 | 441 | 399 | 386 |
| CTE /ppm · K−1 | 5 | 9 | 6 | 9 | 10 | 11 | 18 | 27 |
| 1 wt % weight loss temperature / ° C. | 544 | 531 | 529 | 529 | 528 | 527 | 525 | 523 |
| Light transmittance at 450 nm / % | 76 | 77 | 73 | 76 | 76 | 77 | 79 | 79 |
| YI | 12 | 12 | 15 | 12 | 11 | 10 | 8 | 8 |
| Haze / % | 0.4 | 0.3 | 0.3 | 0.3 | 0.3 | 0.3 | 0.3 | 0.3 |
| Evaluation of glass laminate | | | | | | | | |
| Peel strength /gf · cm−1 | 200 | >400 | >400 | 300 | >400 | >400 | >400 | >400 |
| Evaluation of silicon wafer laminate | | | | | | | | |
| Residual stress / MPa | <4 | 6 | <4 | 6 | 7 | 8 | 15 | 20 |
| Evaluation of SiO/SiN laminate | | | | | | | | |
| Adhesion test | ∘ | ∘ | ∘ | ∘ | ∘ | ∘ | ∘ | ∘ |

The amount of the imidazole compound is expressed in units of eq (mol per 1 mol of repeating unit).

TABLE 5

| | | Example | Example | Comp-Ex | Example | Example | Example | Example | Example |
|---|---|---|---|---|---|---|---|---|---|
| | | 19 | 20 | 10 | 21 | 22 | 23 | 24 | 25 |
| Acid dianhydride | ODPA | 50 | 50 | 60 | 70 | 70 | 70 | 70 | 70 |
| | s-BPDA | 50 | 30 | | 30 | 30 | 30 | 30 | 30 |
| | 6FDA | | 20 | | | | | | |
| | DSDA | | | | | | | | |
| | PMDA | | | 40 | | | | | |
| Diamine | 4-BAAB | 80 | 100 | 100 | 100 | 100 | 100 | 100 | 100 |
| | BAPB | | | | | | | | |
| | 4,4-ODA | 20 | | | | | | | |
| Imidazole | 2-Pz | 0.025 | 0.025 | 0.025 | | | | | |
| compound | Bz | | | | 0.025 | | | | |
| | Im | | | | | 0.025 | | | |
| | 1-Pz | | | | | | 0.025 | 0.01 | 0.005 |

| | | | | | | | | |
|---|---|---|---|---|---|---|---|---|
| Cure temperature / ° C. | 420 | 450 | 450 | 450 | 450 | 450 | 450 | 450 |
| Evaluation of Varnish | | | | | | | | |
| viscosity stability | ∘ | ∘ | ∘ | ∘ | ∘ | ∘ | ∘ | ∘ |
| Evaluation of Film | | | | | | | | |
| Elastic modulus / GPa | 7.0 | 7.4 | 8.0 | 9.3 | 9.2 | 9.2 | 8.9 | 8.9 |
| Elongation at break / % | 57 | 46 | 50 | 35 | 42 | 39 | 41 | 40 |
| Breaking strength / MPa | 494 | 382 | 469 | 444 | 482 | 479 | 510 | 507 |
| CTE /ppm · K−1 | 21 | 21 | 18 | 10 | 10 | 11 | 9 | 9 |
| 1 wt % weight loss temperature / ° C. | 526 | 513 | 521 | 529 | 529 | 529 | 529 | 528 |
| Light transmittance at 450 nm / % | 76 | 78 | 68 | 76 | 76 | 76 | 76 | 76 |
| YI | 11 | 9 | 24 | 11 | 11 | 11 | 11 | 11 |
| Haze / % | 0.5 | 0.5 | 0.4 | 0.3 | 0.3 | 0.3 | 0.3 | 0.3 |
| Evaluation of glass laminate | | | | | | | | |
| Peel strength /gf · cm−1 | >400 | >400 | >400 | >400 | >400 | >400 | >400 | >400 |
| Evaluation of silicon wafer laminate | | | | | | | | |
| Residual stress / MPa | 15 | 16 | 20 | 7 | 7 | 7 | 6 | 6 |
| Evaluation of SiO/SiN laminate | | | | | | | | |
| Adhesion test | ∘ | ∘ | ∘ | ∘ | ∘ | ∘ | ∘ | ∘ |

The amount of the imidazole compound is expressed in units of eq (mol per 1 mol of repeating unit).

[Adhesion Test after Formation of Inorganic Thin Film]

SiOx and SiNx were deposited to a thickness of 400 nm each in this order on the polyimide film surface of the polyimide film/substrate laminate produced in the same manner as in the Examples and Comparative Examples by plasma CVD. Then, annealing was performed in an annealing furnace at 430° C. for 60 minutes. The laminate was removed from the annealing furnace and visually observed to check peeling between the polyimide film and the glass substrate, and between the polyimide film and the SiOx film. The sample in which peeling was not observed on either side was evaluated as “∘ (good)”, and the sample in which peeling was observed on either side was evaluated as “x (bad)”. The results are shown in Tables 2 to 5.

[Adhesion test after formation of inorganic thin film 2]

SiOx and SiNx were deposited to a thickness of 400 nm each in this order on the polyimide film surface of the polyimide film/substrate laminate produced in the same manner as in the Examples and Comparative Examples by plasma CVD. Then, annealing was performed in an annealing furnace at 430° C. for 8 hours. The laminate was removed from the annealing furnace and visually observed to check peeling between the polyimide film and the glass substrate, and between the polyimide film and the SiOx film. The sample in which peeling was not observed on either side was evaluated as “∘ (good)”, and the sample in which peeling was observed on either side was evaluated as “x (bad)”. The results are shown in Table 6.

TABLE 6

| | | Example | Example | Comp-Ex | Example | Comp-Ex | Example | Example |
|---|---|---|---|---|---|---|---|---|
| | | 8 | 26 | 11 | 27 | 12 | 24 | 28 |
| Acid dianhydride | ODPA | 70 | | | 30 | 30 | 70 | 50 |
| | s-BPDA | 30 | 100 | 100 | 70 | 70 | 30 | 50 |
| | 6FDA | | | | | | | |
| | DSDA | | | | | | | |
| | PMDA | | | | | | | |
| Diamine | 4-BAAB | 100 | 100 | 100 | 100 | 100 | 100 | 80 |
| | BAPB | | | | | | | |
| | 4,4-ODA | | | | | | | 20 |
| Imidazole | 2-Pz | 0.025 | 0.025 | | 0.025 | | | 0.025 |
| compound | 1-Pz | | | | | | 0.01 | |

| | | | | | | | |
|---|---|---|---|---|---|---|---|
| Cure temperature / ° C. | 450 | 450 | 450 | 450 | 450 | 450 | 450 |
| Evaluation of SiO/SiN laminate | | | | | | | |
| Adhesion test(430° C. × 8 h) | ∘ | ∘ | x | ∘ | x | ∘ | ∘ |

The amount of the imidazole compound is expressed in units of eq (mol per 1 mol of repeating unit).

From the above results, when the total amount of ODPA and s-BPDA in the tetracarboxylic acid component is 70 mol % or more and the ratio of ODPA is 50 mol % or more, the peel strength is extremely high and exceeds 400 gf/cm, and the improvement of the 450 nm light transmittance and the decrease of the yellow index (YI) are significantly observed. It was also confirmed that the addition of an imidazole compound is effective in improving the 450 nm light transmittance and decreasing the yellow index (YI). It was also confirmed that when an imidazole compound is added in an amount of 0.01 mol or more and less than 1 mol, the effects of high peel strength, high 450 nm light transmittance, and low yellow index (YI) were obtained when the total amount of ODPA and s-BPDA in the tetracarboxylic acid component is 70 mol % or more (even when the ratio of ODPA is less than 50 mol %).

### [Example of Silane Compound Addition]

### Examples 29 to 34, 40 to 43, Reference Example 13

As in Example 7 and the like, the tetracarboxylic acid component and the diamine component were changed to the compounds and amounts (molar ratios) shown in Table 7, and a polyimide precursor composition was obtained by reacting in the same manner as in Example 1.

As a silane compound, the compound and the amount (parts by mass per 100 parts by mass of the total of the tetracarboxylic acid component and the diamine component) shown in Table 7 were mixed with the polyimide precursor solution synthesized above and stirred at room temperature for 3 hours to obtain a homogeneous and viscous polyimide precursor composition. Using the obtained polyimide precursor composition, a polyimide film was produced in the same manner as in Example 1, except that the maximum heating temperature for imidization was 450° C., and the physical properties of the film were evaluated.

### Examples 35 to 39

As in Example 8 and the like, the tetracarboxylic acid component and the diamine component in Example 1 were changed to the compounds and amounts (molar ratios) shown in Table 8, and a polyimide precursor solution was obtained by reacting in the same manner as in Example 1. The imidazole compound solution was mixed with the polyimide precursor solution so that the amount of the imidazole compound was the amount shown in Table 8. For Examples 36 to 39, the compound and amount (parts by mass based on 100 parts by mass of the total of the tetracarboxylic acid component and the diamine component) shown in Table 8 as the silane compound were mixed with the polyimide precursor solution synthesized above, and the mixture was stirred at room temperature for 3 hours to obtain a homogeneous and viscous polyimide precursor composition. Using the obtained polyimide precursor composition, a polyimide film was produced in the same manner as in Example 1, except that the maximum heating temperature for imidization was 450° C., and the film properties were evaluated. For comparison, Example 35 had the same composition as Examples 36 to 39, except that the silane compound was not added, but Example 35 is a working example of the present application.

### Examples 44 to 50

As in Examples 7, 8 and the like, the tetracarboxylic acid component and the diamine component in Example 1 were changed to the compounds and amounts (molar ratios) shown in Table 9, and a polyimide precursor solution was obtained by reacting in the same manner as in Example 1. For Examples 47 and 48, the imidazole compound solution was mixed with the polyimide precursor solution so that the amount of the imidazole compound was the amount shown in Table 9. For Examples 45, 46 and 48 to 50, the compound and amount (parts by mass based on 100 parts by mass of the total of the tetracarboxylic acid component and the diamine component) shown in Table 9 as the silane compound were mixed with the polyimide precursor solution synthesized above, and the mixture was stirred at room temperature for 3 hours to obtain a homogeneous and viscous polyimide precursor composition. Using the obtained polyimide precursor composition, a polyimide film was produced in the same manner as in Example 1, except that the maximum heating temperature for imidization was 450° C., and the film properties were evaluated. For comparison, Examples 44 and 47 are examples in which the silane compound was not added, but these are working examples of the present application.

### Examples 51 to 53

As in Example 8 and the like, the tetracarboxylic acid component and the diamine component in Example 1 were changed to the compounds and amounts (molar ratios) shown in Table 10, and a polyimide precursor solution was obtained by reacting in the same manner as in Example 1. The imidazole compound solution was mixed with the polyimide precursor solution so that the amount of the imidazole compound was the amount shown in Table 10. For Examples 52 and 53, the compound and amount (parts by mass based on 100 parts by mass of the total of the tetracarboxylic acid component and the diamine component) shown in Table 10 as the silane compound were mixed with the polyimide precursor solution synthesized above, and the mixture was stirred at room temperature for 3 hours to obtain a homogeneous and viscous polyimide precursor composition. Using the obtained polyimide precursor composition, a polyimide film was produced in the same manner as in Example 1, except that the maximum heating temperature for imidization was 450° C., and the film properties were evaluated. For comparison, Example 51 is a example in which the silane compound was not added, but it is a working example of the present application.

For Examples 51 to 53, the peel strength test of the glass laminate and the measurement of the residual stress of the silicon wafer laminate were performed in the same manner as in Example 1. Furthermore, peeling between the polyimide film and the glass substrate, and between the polyimide film and the SiOₓ film were observed in the same manner as in the above [Adhesion test 2 after forming an inorganic thin film]. The measurement and evaluation results are shown in Table 10.

TABLE 7

| | | Example | Example | Example | Example | Example | Example |
|---|---|---|---|---|---|---|---|
| | | 29 | 30 | 31 | 32 | 33 | 34 |
| Acid dianhydride | ODPA | 70 | 70 | 70 | 70 | 70 | 70 |
| | s-BPDA | 30 | 30 | 30 | 30 | 30 | 30 |
| | 6FDA | | | | | | |
| | DSDA | | | | | | |
| | PMDA | | | | | | |
| Diamine | 4-BAAB | 100 | 100 | 100 | 100 | 100 | 100 |
| | BAPB | | | | | | |
| | 4,4-ODA | | | | | | |
| Imidazole | 2-Pz | | | | | | |
| compound | | | | | | | |
| Silane | KBM-103 | 0.5 | 2 | 5 | 10 | 20 | 30 |
| compound | KBM-202SS | | | | | | |
| | HIVAC-F-5 | | | | | | |

| | | | | | | |
|---|---|---|---|---|---|---|
| Cure temperature / ° C. | 450 | 450 | 450 | 450 | 450 | 450 |
| Evaluation of Varnish | | | | | | |
| viscosity stability | ∘ | ∘ | ∘ | ∘ | ∘ | ∘ |
| Evaluation of Film | | | | | | |
| Elastic modulus / GPa | 9.1 | 9.0 | 8.6 | 8.2 | 7.9 | 7.5 |
| Elongation at break / % | 38 | 32 | 39 | 37 | 29 | 35 |
| Breaking strength / MPa | 510 | 460 | 501 | 464 | 375 | 367 |
| CTE /ppm · K−1 | 9 | 8 | 11 | 10 | 15 | 21 |
| 1 wt % weight loss temperature / ° C. | 530 | 529 | 531 | 530 | 527 | 524 |
| Light transmittance at 450 nm / % | 75 | 76 | 77 | 78 | 80 | 80 |
| YI | 12 | 11 | 11 | 10 | 10 | 10 |
| Haze / % | 0.4 | 0.3 | 0.4 | 0.4 | 0.4 | 0.4 |

| | | Example | Example | Example | Example | Ref-Ex |
|---|---|---|---|---|---|---|
| | | 40 | 41 | 42 | 43 | 13 |
| Acid dianhydride | ODPA | 70 | 70 | 70 | 70 | 70 |
| | s-BPDA | 30 | 30 | 30 | 30 | 30 |
| | 6FDA | | | | | |
| | DSDA | | | | | |
| | PMDA | | | | | |
| Diamine | 4-BAAB | 100 | 100 | 100 | 100 | 100 |
| | BAPB | | | | | |
| | 4,4-ODA | | | | | |
| Imidazole | 2-Pz | | | | | |
| compound | | | | | | |
| Silane | KBM-103 | | | | | |
| compound | KBM-202SS | 0.5 | 2 | 5 | 10 | |
| | HIVAC-F-5 | | | | | 10 |

| | | | | | |
|---|---|---|---|---|---|
| Cure temperature / ° C. | 450 | 450 | 450 | 450 | 450 |
| Evaluation of Varnish | | | | | |
| viscosity stability | ∘ | ∘ | ∘ | ∘ | ∘ |
| Evaluation of Film | | | | | |
| Elastic modulus / GPa | 8.8 | 8.8 | 8.2 | 7.9 | 7.6 |
| Elongation at break / % | 36 | 31 | 33 | 32 | 32 |
| Breaking strength / MPa | 470 | 442 | 446 | 414 | 377 |
| CTE /ppm · K−1 | 8 | 7 | 8 | 9 | 11 |
| 1 wt % weight loss temperature / ° C. | 527 | 526 | 522 | 521 | 487 |
| Light transmittance at 450 nm / % | 75 | 76 | 76 | 77 | 76 |
| YI | 12 | 11 | 12 | 11 | 12 |
| Haze / % | 0.4 | 0.4 | 0.3 | 0.4 | 0.4 |

The content of the silane compound is parts by mass based on 100 parts by mass of the tetracarboxylic dianhydride and diamine.
Ref-Ex: Reference Example

TABLE 8

| | | Example | Example | Example | Example | Example |
|---|---|---|---|---|---|---|
| | | 35 | 36 | 37 | 38 | 39 |
| Acid dianhydride | ODPA | 70 | 70 | 70 | 70 | 70 |
| | s-BPDA | 30 | 30 | 30 | 30 | 30 |
| | 6FDA | | | | | |
| | DSDA | | | | | |
| | PMDA | | | | | |
| Diamine | 4-BAAB | 100 | 100 | 1.00 | 100 | 100 |
| | BAPB | | | | | |
| | 4,4-ODA | | | | | |
| Imidazole | 2-Pz | 0.01 | 0.01 | 0.01 | 0.01 | 0.01 |
| compound | | | | | | |
| Silane | KBM-103 | | 2 | 5 | 10 | 20 |
| compound | KBM-202SS | | | | | |
| | HIVAC-F-5 | | | | | |

| | | | | | |
|---|---|---|---|---|---|
| Cure temperature / ° C. | 450 | 450 | 450 | 450 | 450 |
| Evaluation of Varnish | | | | | |
| viscosity stability | ∘ | ∘ | ∘ | ∘ | ∘ |
| Evaluation of Film | | | | | |
| Elastic modulus / GPa | 8.7 | 9.4 | 9.4 | 8.9 | 8.4 |
| Elongation at break / % | 36 | 33 | 36 | 38 | 31 |
| Breaking strength / MPa | 476 | 455 | 494 | 460 | 407 |
| CTE /ppm · K−1 | 8 | 10 | 10 | 12 | 12 |
| 1 wt % weight loss temperature / ° C. | 531 | 531 | 531 | 534 | 532 |
| Light transmittance at 450 nm / % | 75 | 76 | 77 | 78 | 78 |
| YI | 11 | 11 | 10 | 10 | 9 |
| Haze / % | 0.3 | 0.4 | 0.4 | 0.4 | 0.4 |

The amount of the imidazole compound is expressed in units of eq (mol per 1 mol of repeating unit).
The content of the silane compound is parts by mass based on 100 parts by mass of the tetracarboxylic dianhydride and diamine.

TABLE 9

| | | Example | Example | Example | Example | Example | Example | Example |
|---|---|---|---|---|---|---|---|---|
| | | 44 | 45 | 46 | 47 | 48 | 49 | 50 |
| Acid dianhydride | ODPA | 60 | 60 | 60 | 60 | 60 | 50 | 50 |
| | s-BPDA | 40 | 40 | 40 | 40 | 40 | 50 | 30 |
| | 6FDA | | | | | | | 20 |
| | DSDA | | | | | | | |
| | PMDA | | | | | | | |
| Diamine | 4-BAAB | 100 | 100 | 100 | 100 | 100 | 80 | 100 |
| | BAPB | | | | | | | |
| | 4,4-ODA | | | | | | 20 | |
| Imidazole | 2-Pz | | | | 0.015 | 0.015 | | |
| compound | | | | | | | | |
| Silane | KBM-103 | | 5 | 10 | | 10 | 20 | 20 |
| compound | KBM-202SS | | | | | | | |
| | HIVAC-F-5 | | | | | | | |

| | | | | | | | |
|---|---|---|---|---|---|---|---|
| Cure temperature / ° C. | 450 | 450 | 450 | 450 | 450 | 420 | 450 |
| Evaluation of Varnish | | | | | | | |
| viscosity stability | ∘ | ∘ | ∘ | ∘ | ∘ | ∘ | ∘ |
| Evaluation of Film | | | | | | | |
| Elastic modulus / GPa | 8.7 | 8.5 | 8.2 | 8.5 | 7.9 | 6.0 | 7.2 |
| Elongation at break / % | 30 | 35 | 42 | 33 | 45 | 45 | 35 |
| Breaking strength / MPa | 450 | 445 | 435 | 447 | 452 | 433 | 332 |
| CTE /ppm · K-1 | 8 | 10 | 14 | 11 | 16 | 18 | 15 |
| 1 wt % weight loss temperature / ° C. | 530 | 530 | 530 | 532 | 532 | 523 | 512 |
| Light transmittance at 450 nm / % | 72 | 74 | 75 | 77 | 77 | 77 | 76 |
| YI | 16 | 14 | 14 | 12 | 12 | 10 | 11 |
| Haze / % | 0.3 | 0.3 | 0.3 | 0.3 | 0.3 | 0.3 | 0.3 |

The amount of the imidazole compound is expressed in units of eq (mol per 1 mol of repeating unit).
The content of the silane compound is parts by mass based on 100 parts by mass of the tetracarboxylic dianhydride and diamine.

TABLE 10

| | | Example | Example | Example |
|---|---|---|---|---|
| | | 51 | 52 | 53 |
| Acid dianhydride | ODPA | 50 | 50 | 50 |
| | s-BPDA | 50 | 50 | 50 |
| | 6FDA | | | |
| | DSDA | | | |
| | PMDA | | | |
| Diamine | 4-BAAB | 100 | 100 | 100 |
| | BAPB | | | |
| | 4,4-ODA | | | |
| Imidazole | 2-Pz | 0.025 | 0.025 | 0.025 |
| compound | | | | |
| Silane | KBM-103 | | 30 | 50 |
| compound | KBM-202SS | | | |
| | HIVAC-F-5 | | | |

| | | | |
|---|---|---|---|
| Cure temperature/° C. | 450 | 450 | 450 |
| Evaluation of Varnish | | | |
| viscosity stability | ◯ | ◯ | ◯ |
| Evaluation of Film | | | |
| Elastic modulus/GPa | 8.2 | 6.6 | 5.8 |
| Elongation at break/% | 36 | 27 | 32 |
| Breaking strength/MPa | 456 | 311 | 302 |
| CTE/ppm · K − 1 | 10 | 17 | 24 |
| 1 wt % weight loss temperature/° C. | 535 | 532 | 530 |
| Light transmittance at 450 nm/% | 76 | 81 | 83 |
| YI | 12 | 10 | 8 |
| Haze/% | 0.3 | 0.3 | 0.3 |
| Evaluation of glass laminate | | | |
| Peel strength/gf · cm − 1 | >400 | >400 | >400 |
| Evaluation of silicon wafer laminate | | | |
| Residual stress/Mpa | 11 | 16 | 18 |
| Evaluation of SiO/SiN laminate | | | |
| Adhesion test(430° C. × 8 h) | ◯ | ◯ | ◯ |

The amount of the imidazole compound is expressed in units of eq (mol per 1 mol of repeating unit).
The content of the silane compound is parts by mass based on 100 parts by mass of the tetracarboxylic dianhydride and diamine.

With reference to Table 7, Examples in which the silane compounds (KBM-103 and KBM-202SS) were added showed a further improvement in 450 nm light transmittance compared to Example 7. Although the 450 nm light transmittance was improved in Reference Example 13 as well, the 1% weight loss temperature was significantly lowered, indicating a poor heat resistance. With reference to Table 8, it was confirmed that the addition of the silane compound improved the 450 nm light transmittance also in the systems containing an imidazole compound.

Similar trends were observed in Tables 9 and 10.

### INDUSTRIAL APPLICABILITY

The present invention is suitably applied to the manufacture of flexible electronic devices, for example, display devices including flexible displays such as liquid crystal displays and organic EL displays, and electronic papers, and light receiving devices such as solar cells and CMOS.

What is claimed is:

1. A polyimide precursor composition, comprising a polyimide precursor having a repeating unit represented by the following general formula (I) and at least one imidazole compound as an optional component in an amount of less than 1 mol per 1 mol of a repeating unit of the polyimide precursor: 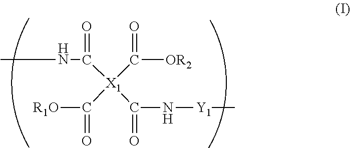
wherein in general formula I, X₁ is a tetravalent aliphatic group or aromatic group, Y₁ is a divalent aliphatic group or aromatic group, R₁ and R₂ are each independently a hydrogen atom, an alkyl group having 1 to 6 carbon atoms or an alkylsilyl group having 3 to 9 carbon atoms, wherein,
X₁ satisfies (i);
(i) X₁ comprises a structure represented by formula (1-1) in an amount of 50 mol % or more, and comprises a structure represented by formula (1-1) and a structure represented by formula (1-2) in an amount of 70 mol % or more in total; 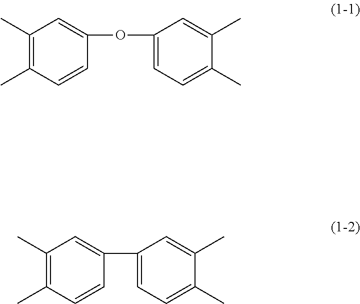
Y₁ comprises a structure represented by formula (B) in an amount of 70 mol % or more, with the proviso that Y₁ does not comprise a structure including a nitrogen-containing heterocycle in an amount of 3 to 8 mol %;

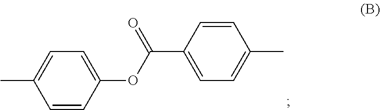

2. The polyimide precursor composition according to claim 1, wherein 60 mol % or more of X₁ is a structure represented by formula (1-1).

3. The polyimide precursor composition according to claim 1, wherein 80 mol % or more of Y₁ has a structure represented by formula (B).

4. The polyimide precursor composition according to claim 1, further comprising at least one imidazole compound in an amount of 0.01 mol or more and less than 1 mol per 1 mol of a repeating unit of the polyimide precursor.

5. The polyimide precursor composition according to claim 4, wherein the imidazole compound is at least one selected from the group consisting of 1,2-dimethylimidazole, 1-methylimidazole, 2-methylimidazole, 2-phenylimidazole, 1-phenylimidazole, imidazole and benzimidazole.

6. (canceled)

7. (canceled)

8. A polyimide film obtained from the polyimide precursor composition according to claim 1.

9. A polyimide film/substrate laminate comprising:
a polyimide film obtained from the polyimide precursor composition according to claim 1, and
a substrate.

10. The laminate according to claim 9, further comprising an inorganic thin film layer on the polyimide film of the laminate.

11. The laminate according to claim 9, wherein the substrate is a glass substrate.

12. A method for producing a polyimide film/substrate laminate, comprising:
(a) applying the polyimide precursor composition according to claim 1 onto a substrate; and
(b) heat-treating the polyimide precursor on the substrate to laminate a polyimide film on the substrate.

13. The method for producing a laminate according to claim 12, further comprising, after step (b),
(c) forming an inorganic thin film layer on the polyimide film of the laminate.

14. A method for manufacturing a flexible electronic device, comprising:
(d) forming at least one layer selected from a conductive layer and a semiconductor layer on the inorganic thin film layer of the laminate produced according to claim 13; and
(e) peeling the polyimide film from the substrate.

15. (canceled)

16. (canceled)

17. A polyimide precursor composition, comprising a polyimide precursor having a repeating unit represented by the following general formula (I) and at least one imidazole compound as an optional component in an amount of less than 1 mol per 1 mol of a repeating unit of the polyimide precursor: 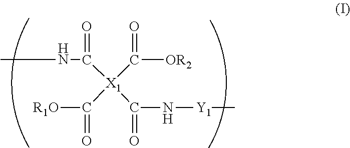
wherein in general formula I, X₁ is a tetravalent aliphatic group or aromatic group, Y₁ is a divalent aliphatic group or aromatic group, R₁ and R₂ are each independently a hydrogen atom, an alkyl group having 1 to 6 carbon atoms or an alkylsilyl group having 3 to 9 carbon atoms, wherein,
X₁ satisfies (i);
(i) X₁ comprises a structure represented by formula (1-1) in an amount of 50 mol % or more, and comprises a structure represented by formula (1-1) and a structure represented by formula (1-2) in an amount of 70 mol % or more in total; 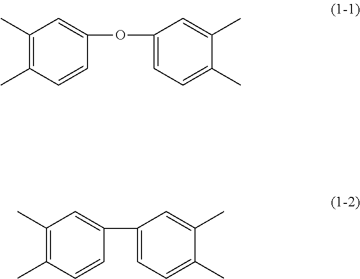
Y₁ comprises a structure represented by formula (B) in an amount of 70 mol % or more; 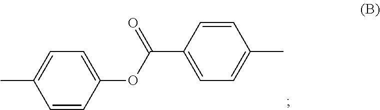
wherein the polyimide precursor composition is for producing a polyimide film used as a flexible display substrate.

18. The polyimide precursor composition according to claim 17, wherein 60 mol % or more of X₁ is a structure represented by formula (1-1).

19. The polyimide precursor composition according to claim 17, wherein 80 mol % or more of Y₁ has a structure represented by formula (B).

20. The polyimide precursor composition according to claim 17, further comprising at least one imidazole compound in an amount of 0.01 mol or more and less than 1 mol per 1 mol of a repeating unit of the polyimide precursor.

21. The polyimide precursor composition according to claim 20, wherein the imidazole compound is at least one selected from the group consisting of 1,2-dimethylimidazole, 1-methylimidazole, 2-methylimidazole, 2-phenylimidazole, 1-phenylimidazole, imidazole and benzimidazole.

22. A polyimide film obtained from the polyimide precursor composition according to claim 17.

23. A polyimide film/substrate laminate comprising:
a polyimide film obtained from the polyimide precursor composition according to claim 17; and
a substrate.

24. The laminate according to claim 17, further comprising an inorganic thin film layer on the polyimide film of the laminate.

25. The laminate according to claim 17, wherein the substrate is a glass substrate.

26. A method for producing a polyimide film/substrate laminate, comprising:
(a) applying the polyimide precursor composition according to claim 17 onto a substrate; and
(b) heat-treating the polyimide precursor on the substrate to laminate a polyimide film on the substrate.

27. The method for producing a laminate according to claim 26, further comprising, after step (b):
(c) forming an inorganic thin film layer on the polyimide film of the laminate.

28. A method for manufacturing a flexible electronic device, comprising:
(d) forming at least one layer selected from a conductive layer and a semiconductor layer on the inorganic thin film layer of the laminate produced according to claim 27; and
(e) peeling the polyimide film from the substrate.
